(19) United States
(12) Patent Application Publication
(10) Pub. No.: US 2019/0202975 A1
(43) Pub. Date: Jul. 4, 2019

(54) PROCESS FOR MAKING AN ORGANIC CHARGE TRANSPORTING FILM

(71) Applicants: Dow Global Technologies LLC, Midland, MI (US); Rohm and Haas Electronic Materials LLC, Marlborough, MA (US)

(72) Inventors: Chun LIU, Midland, MI (US); Robert David GRIGG, Midland, MI (US); Sukrit MUKHOPADHYAY, Midland, MI (US); Matthew S. REMY, Midland, MI (US); Liam P. SPENCER, Lake Jackson, TX (US); Minrong ZHU, Shanghai (CN); Yang LI, Shanghai (CN); Shaoguang FENG, Shanghai (CN); Kenneth L. KEARNS, Midland, MI (US); Bruce M. BELL, Higgins Lake, MI (US); Anthony P. GIES, Freeport, TX (US); Peter TREFONAS, Medway, MA (US); David D. DEVORE, Midland, MI (US); Emad AQAD, Northborough, MA (US); Ashley INMAN, Midland, MI (US)

(21) Appl. No.: 16/311,886

(22) PCT Filed: Jun. 28, 2016
(86) PCT No.: PCT/CN2016/087409

§ 371 Date: Dec. 20, 2018

(51) Int. Cl. C08G 61/02; C08L 25/04; H01L 51/00; H01L 51/50

(52) U.S. Cl. CPC C08G 61/02; H01L 51/0058; H01L 51/004; H01L 51/506; H01L 51/5076; H01L 51/0035; C08G 2261/1434; C08G 2261/149; C08G 2261/1424; C08G 2261/135; C08G 2261/148; C08G 2261/512; C08G 2261/514; C08G 2261/41; H01L 51/0072; H01L 51/006; C08L 25/04

(57) ABSTRACT

A single liquid phase formulation useful for producing an organic charge transporting film. The formulation contains: (a) a polymer resin having M_{w} at least 3,000 and having arylmethoxy linkages; (b) an acid catalyst which is an organic Bronsted acid with pKa≤4; a Lewis acid comprising a positive aromatic ion and an anion which is (i) a tetraaryl borate having the formula (I) wherein R represents zero to five non-hydrogen substituents selected from D, F and CF₃, (ii) BF₄⁻, (iii) PF₆⁻, (iv) SbF₆⁻, (v) AsF₆⁻ or (vi) ClO₄⁻; or a thermal acid generator.

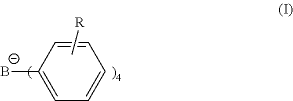

### FIELD OF THE INVENTION

The present invention relates to a process for preparing an organic charge transporting film.

### BACKGROUND OF THE INVENTION

There is a need for an efficient process for manufacturing an organic charge transporting film for use in a flat panel organic light emitting diode (OLED) display. Solution processing is one of the leading technologies for fabricating large flat panel OLED displays by deposition of OLED solution onto a substrate to form a thin film followed by cross-linking and polymerization. Currently, solution processable polymeric materials are cross-linkable organic charge transporting compounds. For example, U.S. Pat. No. 7,037,994 discloses an antireflection film-forming formulation comprising at least one polymer containing an acetoxymethylacenaphthylene or hydroxyl methyl acenaphthylene repeating unit and a thermal or photo acid generator (TAG, PAG) in a solvent. However, this reference does not disclose the formulation described herein.

### SUMMARY OF THE INVENTION

The present invention provides a single liquid phase formulation useful for producing an organic charge transporting film; said formulation comprising: (a) a polymer resin having M_{w} at least 3,000 and comprising arylmethoxy linkages; (b) an acid catalyst which is an organic Bronsted acid with pKa≤4; a Lewis acid comprising a positive aromatic ion and an anion which is (i) a tetraaryl borate having the formula

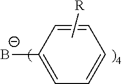

wherein R represents zero to five non-hydrogen substituents selected from D, F and CF₃, (ii) BF₄⁻, (iii) PF₆⁻, (iv) SbF₆⁻, (v) AsF₆⁻ or (vi) ClO₄⁻; or a thermal acid generator (TAG) which is an ammonium or pyridinium salt of an organic Bronsted acid with pKa≤2 or an ester of an organic sulfonic acid; and (c) a solvent.

### DETAILED DESCRIPTION OF THE INVENTION

Percentages are weight percentages (wt %) and temperatures are in ° C., unless specified otherwise. Operations were performed at room temperature (20-25° C.), unless specified otherwise. Boiling points are measured at atmospheric pressure (ca. 101 kPa). Molecular weights are in Daltons and molecular weights of polymers are determined by Size Exclusion Chromatography using polystyrene standards. A “polymer resin” is a monomer, oligomer or polymer which can be cured to form a cross-linked film. Preferably the polymer resins have at least two groups per molecule which are polymerizable by addition polymerization. Examples of polymerizable groups include an ethenyl group (preferably attached to an aromatic ring), benzocyclobutenes, acrylate or methacrylate groups, trifluorovinylether, cinnamate/chalcone, diene, ethoxyethyne and 3-ethoxy-4-methylcyclobut-2-enone. Preferred resins contain at least one of the following structures

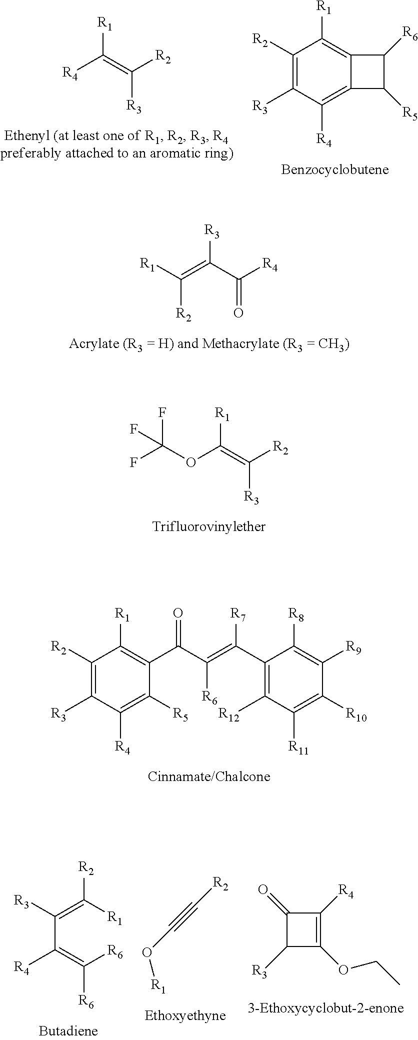

where “R” groups independently are hydrogen, deuterium, C₁-C₃₀ alkyl, hetero-atom substituted C₁-C₃₀ alkyl, C₁-C₃₀ aryl, hetero-atom substituted C₁-C₃₀ aryl or represent another part of the resin structure; preferably hydrogen, deuterium, C₁-C₂₀ alkyl, hetero-atom substituted C₁-C₂₀ alkyl, C₁-C₂₀ aryl, hetero-atom substituted C₁-C₂₀ aryl or represent another part of the resin structure; preferably hydrogen, deuterium, C₁-C₁₀ alkyl, hetero-atom substituted C₁-C₁₀ alkyl, C₁-C₁₀ aryl, hetero-atom substituted C₁-C₁₀ aryl or represent another part of the resin structure; preferably hydrogen, deuterium, C₁-C₄ alkyl, hetero-atom substituted C₁-C₄ alkyl, or represent another part of the resin structure. In one preferred embodiment of the invention, “R” groups may be connected to form fused ring structures.

An arylmethoxy linkage is a linkage having at least one benzylic carbon atom attached to an oxygen atom. Preferably, the arylmethoxy linkage is an ether, an ester or a benzyl alcohol. Preferably, the arylmethoxy linkage has two benzylic carbon atoms attached to an oxygen atom. A benzylic carbon atom is a carbon atom which is not part of an aromatic ring and which is attached to a ring carbon of an aromatic ring having from 5 to 30 carbon atoms (preferably 5 to 20), preferably a benzene ring.

An “organic charge transporting compound” is a material which is capable of accepting an electrical charge and transporting it through the charge transport layer. Examples of charge transporting compounds include “electron transporting compounds” which are charge transporting compounds capable of accepting an electron and transporting it through the charge transport layer, and “hole transporting compounds” which are charge transporting compounds capable of transporting a positive charge through the charge transport layer. Preferably, organic charge transporting compounds. Preferably, organic charge transporting compounds have at least 50 wt % aromatic rings (measured as the molecular weight of all aromatic rings divided by total molecular weight; non-aromatic rings fused to aromatic rings are included in the molecular weight of aromatic rings), preferably at least 60%, preferably at least 70%, preferably at least 80%, preferably at least 90%. Preferably the resins are organic charge transporting compounds.

In a preferred embodiment of the invention, some or all materials used, including solvents and resins, are enriched in deuterium beyond its natural isotopic abundance. All compound names and structures which appear herein are intended to include all partially or completely deuterated analogs.

Preferably, the polymer resin has M_{w} at least 5,000, preferably at least 10,000, preferably at least 20,000; preferably no greater than 10,000,000, preferably no greater than 1,000,000, preferably no greater than 500,000, preferably no greater than 400,000, preferably no greater than 300,000, preferably no greater than 200,000, preferably no greater than 100,000. Preferably, the polymer resin comprises at least 50% (preferably at least 60%, preferably at least 70%, preferably at least 80%, preferably at least 90%) polymerized monomers which contain at least five aromatic rings, preferably at least six, preferably no more than 20, preferably no more than 15; other monomers not having this characteristic may also be present. A cyclic moiety which contains two or more fused rings is considered to be a single aromatic ring, provided that all ring atoms in the cyclic moiety are part of the aromatic system. For example, naphthyl, carbazolyl and indolyl are considered to be single aromatic rings, but fluorenyl is considered to contain two aromatic rings because the carbon atom at the 9-position of fluorene is not part of the aromatic system. Preferably, the resin comprises at least 50% (preferably at least 70%) polymerized monomers which contain at least one of triarylamine, carbazole, indole and fluorene ring systems.

Preferably, the resin comprises a first monomer of formula NAr¹Ar²Ar³, wherein Ar¹, Ar² and Ar³ independently are C₆-C₅₀ aromatic substituents and at least one of Ar¹, Ar² and Ar³ contains a vinyl group attached to an aromatic ring. Preferably, the resin comprises at least 50% of the first monomer, preferably at least 60%, preferably at least 70%, preferably at least 80%, preferably at least 90%. Preferably, the resin is a copolymer of the first monomer and a second monomer of formula (I)

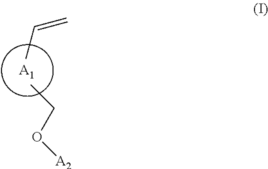

wherein A₁ is an aromatic ring system having from 5 to 20 carbon atoms and in which the vinyl group and the —CH₂OA₂ group are attached to aromatic ring carbons and A₂ is hydrogen or a C₁-C₂₀ organic substituent group. Preferably, A₁ has five or six carbon atoms, preferably it is a benzene ring. Preferably, A₂ is hydrogen or a C₁-C₁₅ organic substituent group, preferably containing no atoms other than carbon, hydrogen, oxygen and nitrogen. The monomer of formula NAr¹Ar²Ar³ preferably comprises a benzyloxy linkage. In a preferred embodiment, the polymer comprises a monomer having formula (I) in which A₂ is a substituent of formula NAr¹Ar²Ar³, as defined above, preferably linked to oxygen via an aromatic ring carbon or a benzylic carbon. Preferably, the compound of formula NAr¹Ar²Ar³ contains a total of 4 to 20 aromatic rings; preferably at least 5 preferably at least 6; preferably no more than 18, preferably no more than 15, preferably no more than 13.

In a preferred embodiment of the invention, the formulation further comprises a monomer or oligomer having M_{w} less than 5,000, preferably less than 3,000, preferably less than 2,000, preferably less than 1,000; preferably a crosslinker having at least three polymerizable vinyl groups.

Preferably, the polymer resins are at least 99% pure, as measured by liquid chromatography/mass spectrometry (LC/MS) on a solids basis, preferably at least 99.5%, preferably at least 99.7%. Preferably, the formulation of this invention contains no more than 10 ppm of metals, preferably no more than 5 ppm.

Preferred polymer resins useful in the present invention include, e.g., the following structures, as well as polymers comprising Monomers A, B & C, as described in the Examples.

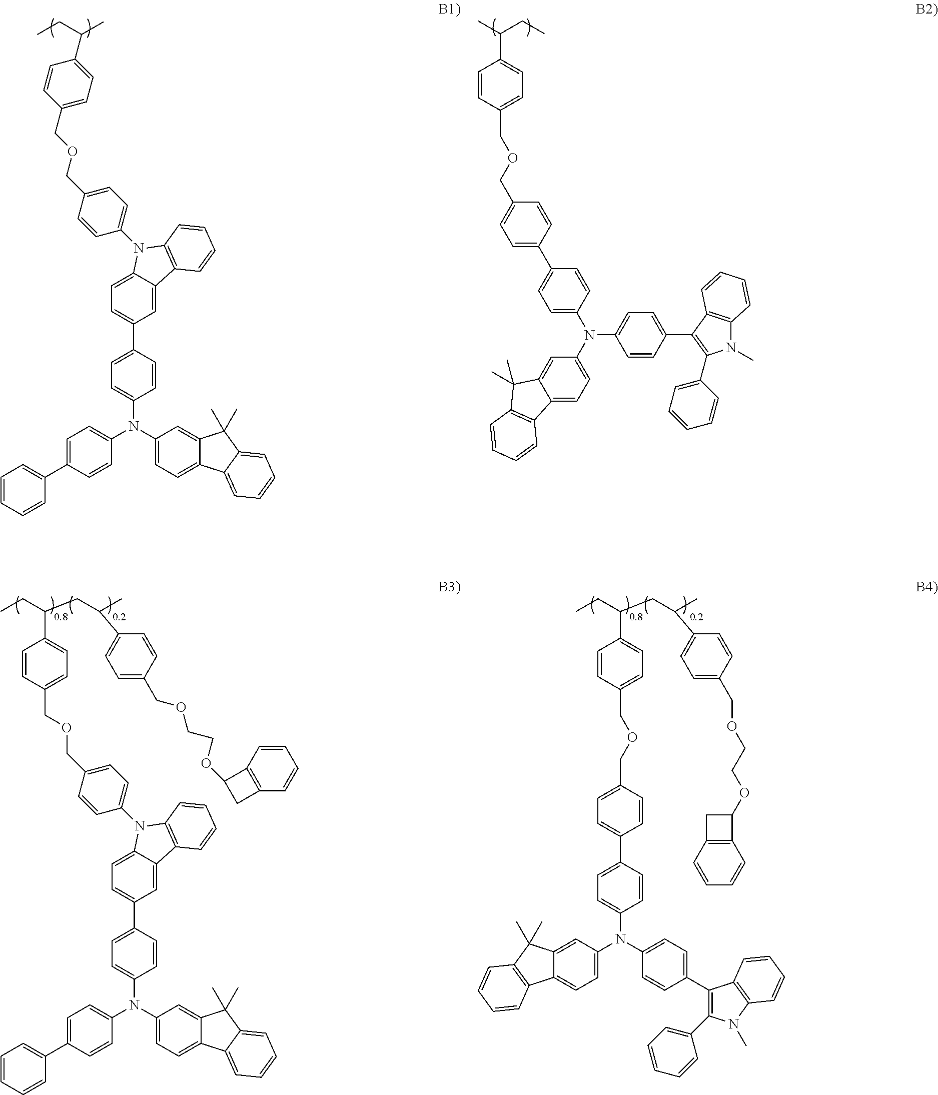

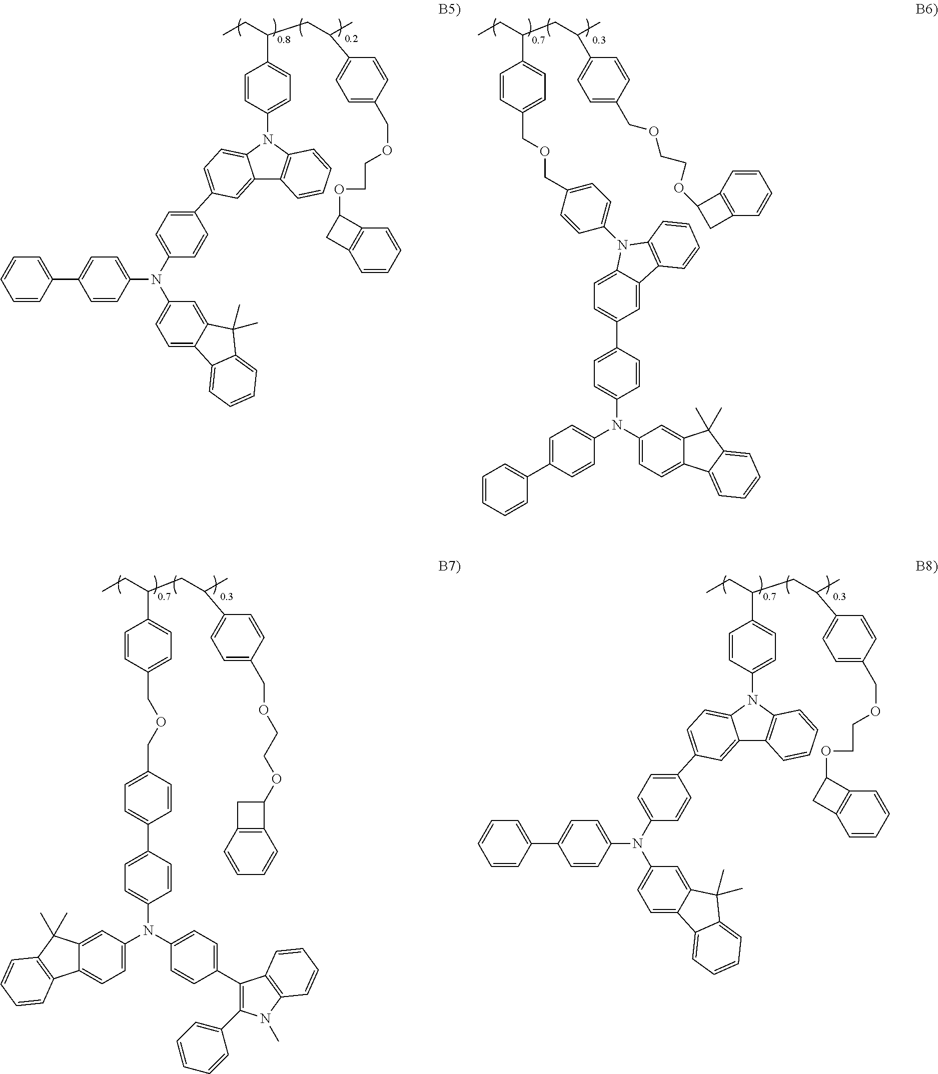

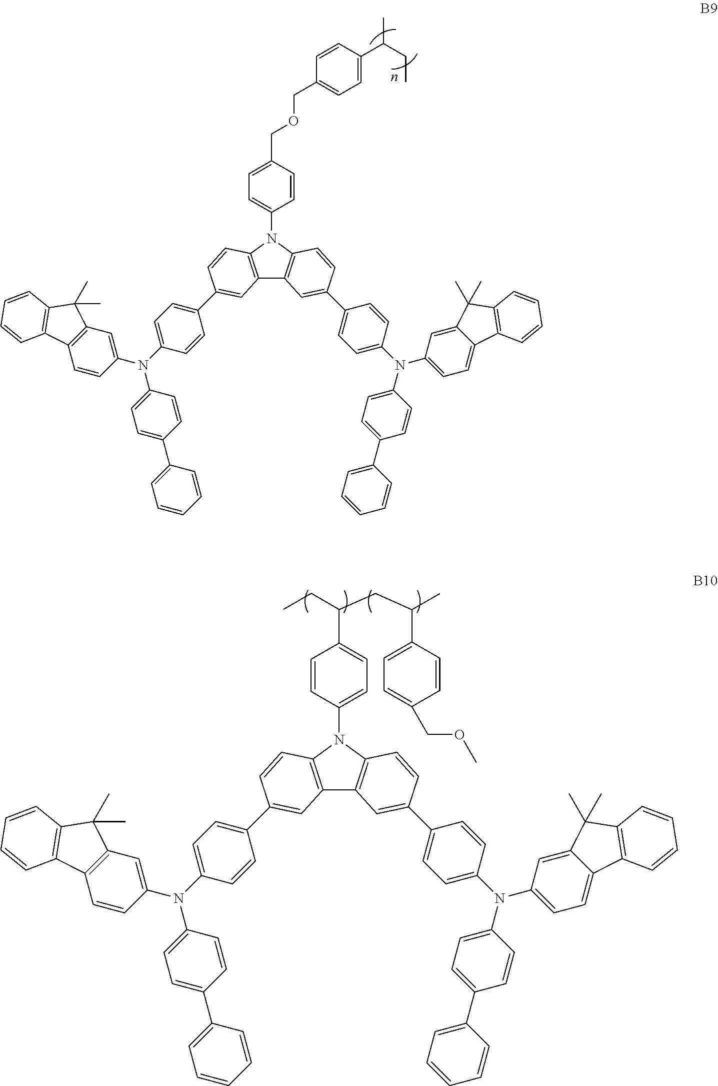

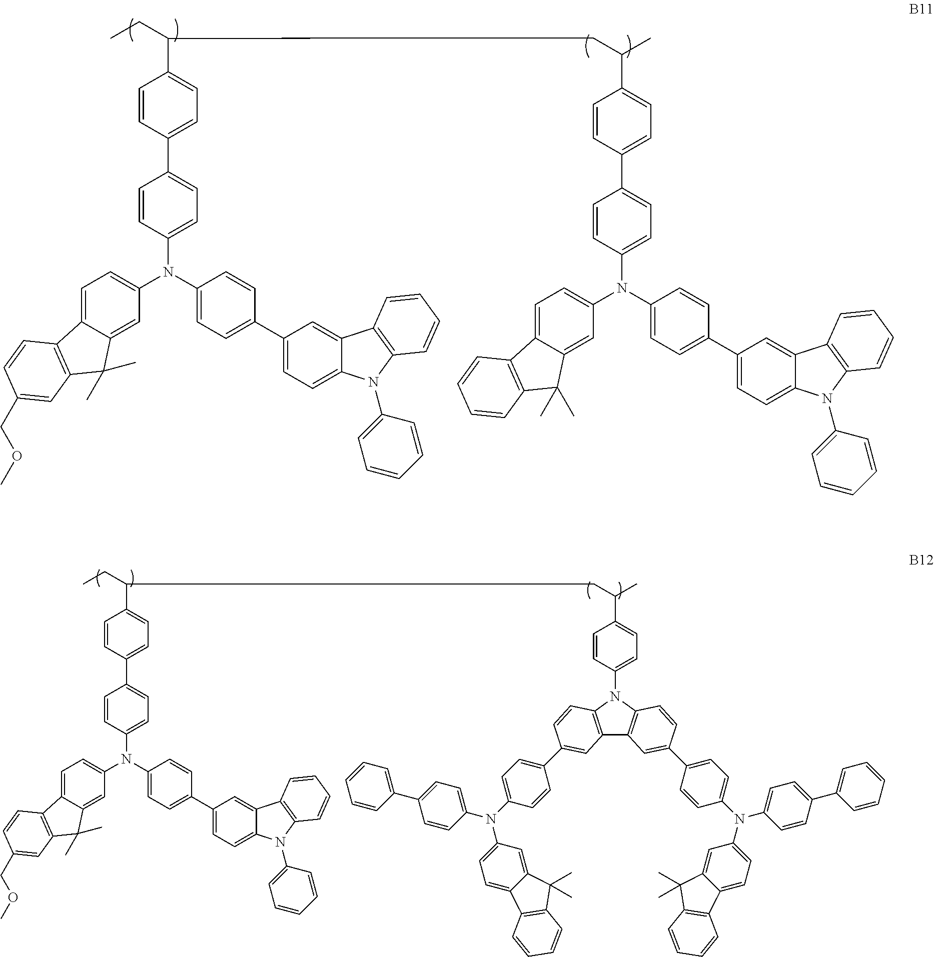

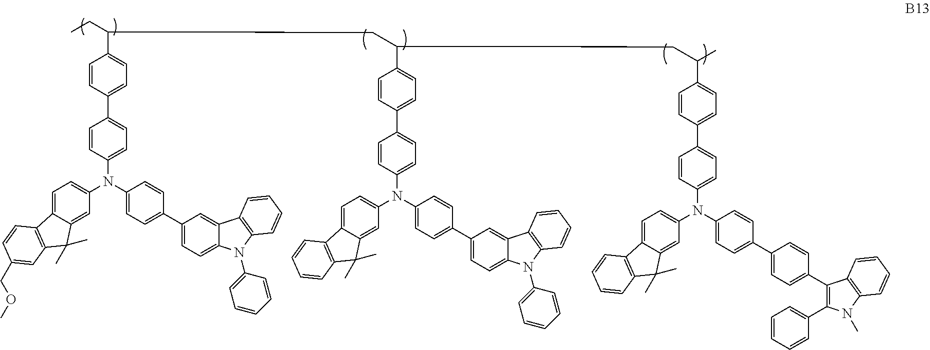

Crosslinking agents which are not necessarily charge transporting compounds may be included in the formulation as well. Preferably, these crosslinking agents have at least 60 wt % aromatic rings (as defined previously), preferably at least 70%, preferably at least 75 wt %. Preferably, the crosslinking agents have from three to five polymerizable groups, preferably three or four. Preferably, the polymerizable groups are ethenyl groups attached to aromatic rings. Preferred crosslinking agents are shown below

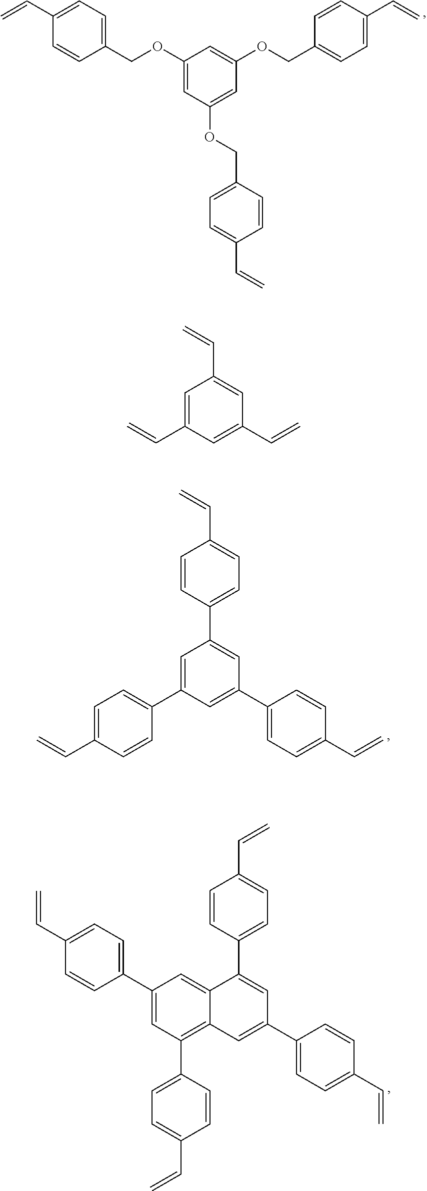

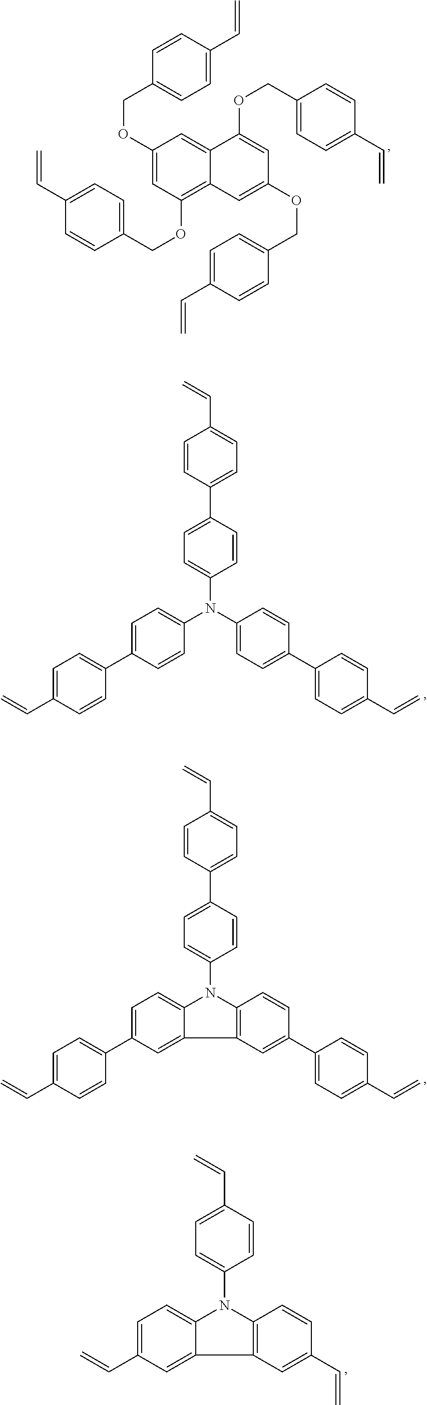

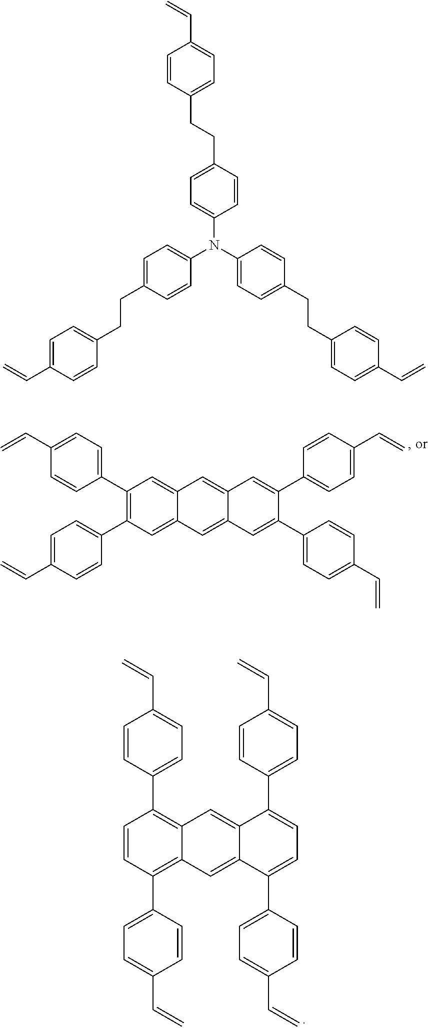

Preferably, the anion is a tetraaryl borate having the formula

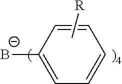

wherein R represents zero to five non-hydrogen substituents selected from F and CF₃. Preferably, R represents five substituents on each of four rings, preferably five fluoro substituents.

Preferably, the positive aromatic ion has from seven to fifty carbon atoms, preferably seven to forty. In a preferred embodiment, the positive aromatic ion is tropylium ion or an ion having the formula

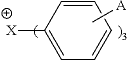

wherein A is a substituent on one or more of the aromatic rings and is H, D, CN, CF₃ or (Ph)₃C+(attached via Ph); X is C, Si, Ge or Sn. Preferably, X is C. Preferably, A is the same on all three rings.

Preferably, the organic Bronsted acid has pKa≤2, preferably ≤0. Preferably, the organic Bronsted acid is an aromatic, alkyl or perfluoroalkyl sulfonic acid; a carboxylic acid; a protonated ether; or a compound of formula Ar⁴SO₃CH₂Ar⁵, wherein Ar⁴ is phenyl, alkylphenyl or trifluoromethylphenyl, and Ar⁵ is nitrophenyl. Preferably, the TAG has a degradation temperature ≤280° C. Especially preferred acid catalysts for use in the present invention include, e.g., the following Bronsted acid, Lewis acid and TAGs.

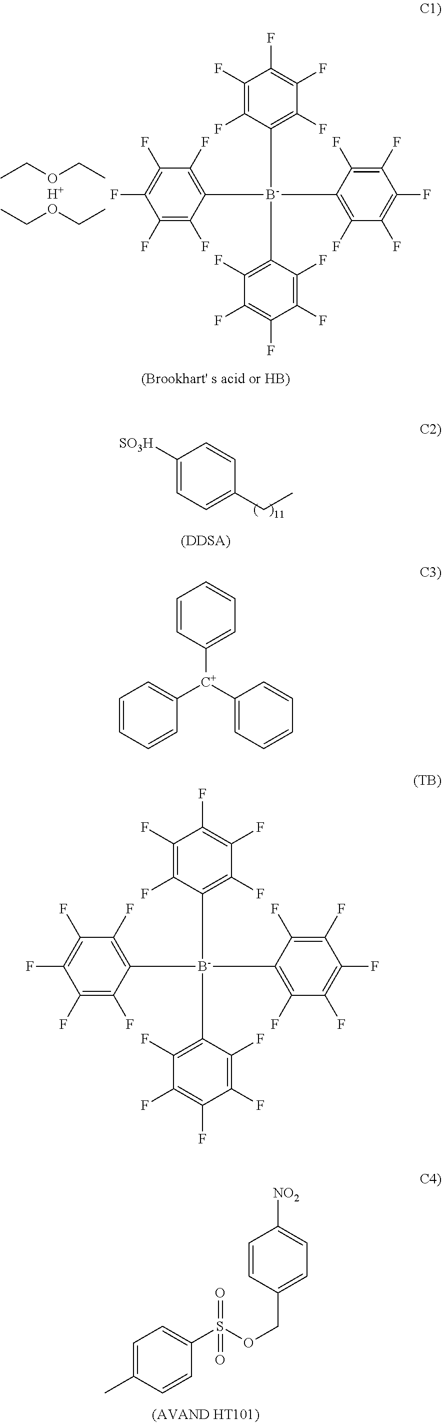

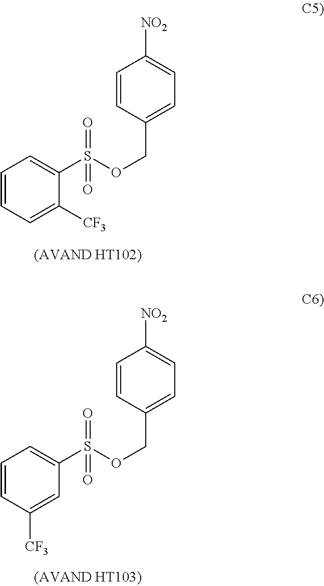 [SMILES: O=[N+]([O-])c1ccc(COS(=O)(=O)c2ccccc2C(F)(F)F)cc1 ; O=[N+]([O-])c1ccc(COS(=O)(=O)c2cccc(C(F)(F)F)c2)cc1]

An especially preferred TAG is an organic ammonium salt. Preferred pyridinium salts include, e.g.,

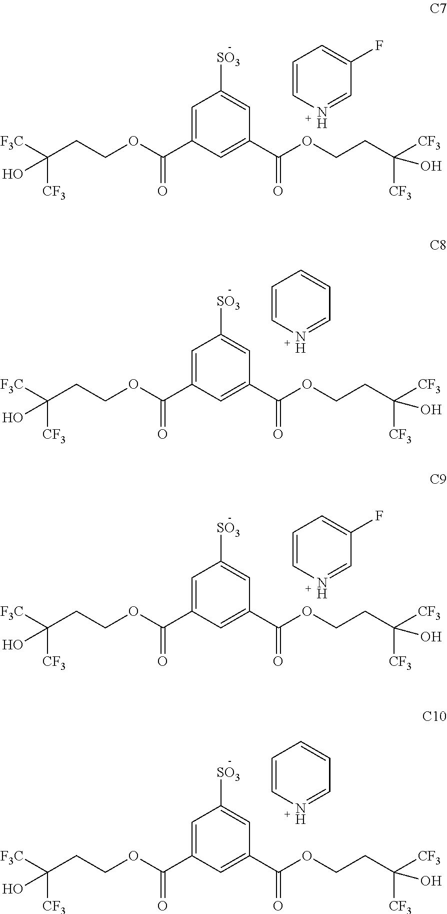

Preferably, the amount of acid is from 0.5 to 10 wt/o of the weight of the polymer, preferably less than 5 wt %, preferably less than 2 wt %.

Preferably, solvents used in the formulation have a purity of at least 99.8%, as measured by gas chromatography-mass spectrometry (GC/MS), preferably at least 99.9%. Preferably, solvents have an RED value (relative energy difference (vs. polymer) as calculated from Hansen solubility parameter using CHEMCOMP v2.8.50223.1) less than 1.2, preferably less than 1.0. Preferred solvents include aromatic hydrocarbons and aromatic-aliphatic ethers, preferably those having from six to twenty carbon atoms. Anisole, xylene and toluene are especially preferred solvents.

Preferably, the percent solids of the formulation, i.e., the percentage of monomers and polymers relative to the total weight of the formulation, is from 0.5 to 20 wt %; preferably at least 0.8 wt %, preferably at least 1 wt %, preferably at least 1.5 wt %; preferably no more than 15 wt %, preferably no more than 10 wt %, preferably no more than 7 wt %, preferably no more than 4 wt %. Preferably, the amount of solvent(s) is from 80 to 99.5 wt %; preferably at least 85 wt %, preferably at least 90 wt %, preferably at least 93 wt %, preferably at least 94 wt %; preferably no more than 99.2 wt %, preferably no more than 99 wt %, preferably no more than 98.5 wt %.

The present invention is further directed to an organic charge transporting film and a process for producing it by coating the formulation on a surface, preferably another organic charge transporting film, and Indium-Tin-Oxide (ITO) glass or a silicon wafer. The film is formed by coating the formulation on a surface, baking at a temperature from 50 to 150° C. (preferably 80 to 120° C.), preferably for less than five minutes, followed by thermal cross-linking at a temperature from 120 to 280° C.; preferably at least 140° C., preferably at least 160° C., preferably at least 170° C.; preferably no greater than 230° C., preferably no greater than 215° C.

Preferably, the thickness of the polymer films produced according to this invention is from 1 nm to 100 microns, preferably at least 10 nm, preferably at least 30 nm, preferably no greater than 10 microns, preferably no greater than 1 micron, preferably no greater than 300 nm. The spin-coated film thickness is determined mainly by the solid contents in solution and the spin rate. For example, at a 2000 rpm spin rate, 2, 5, 8 and 10 wt % polymer resin formulated solutions result in the film thickness of 30, 90, 160 and 220 nm, respectively. The wet film shrinks by 5% or less after baking and cross-linking.

### EXAMPLES

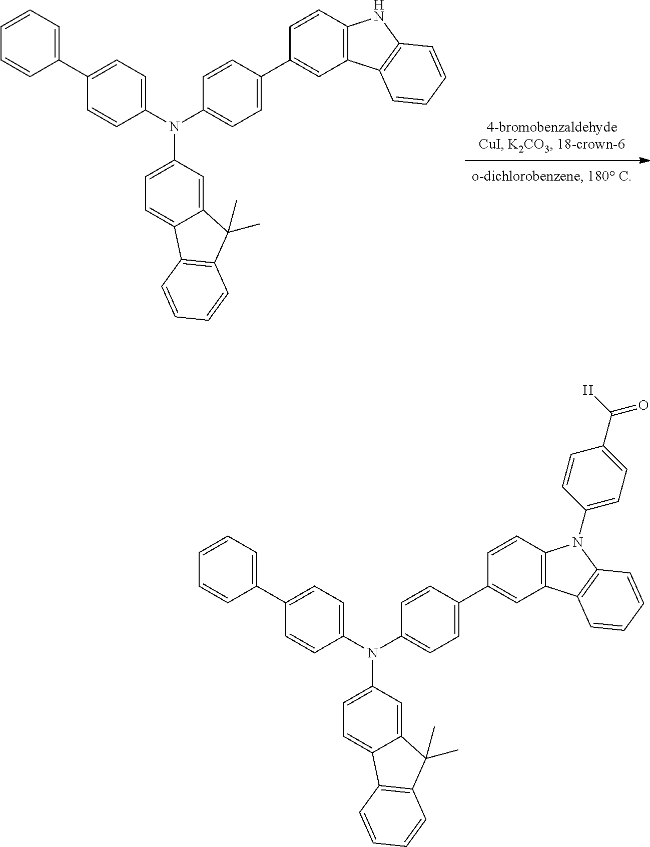 [SMILES: CC1(C)c2ccccc2-c2ccc(N(c3ccc(-c4ccccc4)cc3)c3ccc(-c4ccc5[nH]c6ccccc6c5c4)cc3)cc21 ; CC1(C)c2ccccc2-c2ccc(N(c3ccc(-c4ccccc4)cc3)c3ccc(-c4ccc5c(c4)c4ccccc4n5-c4ccc(C=O)cc4)cc3)cc21]

### Synthesis of 4-(3-(4-([1,1′-biphenyl]-4-yl(9,9-dimethyl-9H-fluoren-2-yl)amino)phenyl)-9H-carbazol-9-yl)benzaldehyde

A round-bottom flask was charged with N-(4-(9H-carbazol-3-yl)phenyl)-N-([1,1′-biphenyl]-4-yl)-9,9-dimethyl-9H-fluoren-2-amine (2.00 g 3.318 mmol, 1.0 equiv), 4-bromobenzaldehyde (0.737 g, 3.982 mmol, 1.2 equiv), CuI (0.126 g 0.664 mmol, 0.2 equiv), potassium carbonate (1.376 g 9.954 mmol, 3.0 equiv), and 18-crown-6 (86 mg 10 mol %). The flask was flushed with nitrogen and connected to a reflux condenser. 10.0 mL dry, degassed 1,2-dichlorobenzene was added, and the mixture was refluxed for 48 hours. The cooled solution was quenched with sat. aq. NH₄Cl, and extracted with dichloromethane. Combined organic fractions were dried, and solvent was removed by distillation. The crude residue was purified by chromatography on silica gel (hexane/chloroform gradient), and gave a bright yellow solid product (2.04 g). The product had the following characteristics: ¹H-NMR (500 MHz, CDCl₃): δ 10.13 (s, 1H), 8.37 (d, J=2.0 Hz, 1H), 8.20 (dd, J=7.7, 1.0 Hz, 1H), 8.16 (d, J=8.2 Hz, 2H), 7.83 (d, J=8.1 Hz, 2H), 7.73-7.59 (m, 7H), 7.59-7.50 (m, 4H), 7.50-7.39 (m, 4H), 7.39-7.24 (m, 10H), 7.19-7.12 (m, 1H), 1.47 (s, 6H). ¹³C-NMR (126 MHz, CDCl₃): δ 190.95, 155.17, 153.57, 147.21, 146.98, 146.69, 143.38, 140.60, 140.48, 139.28, 138.93, 135.90, 135.18, 134.64, 134.46, 133.88, 131.43, 128.76, 127.97, 127.81, 126.99, 126.84, 126.73, 126.65, 126.54, 126.47, 125.44, 124.56, 124.44, 124.12, 123.98, 123.63, 122.49, 120.96, 120.70, 120.57, 119.47, 118.92, 118.48, 110.05, 109.92, 46.90, 27.13.

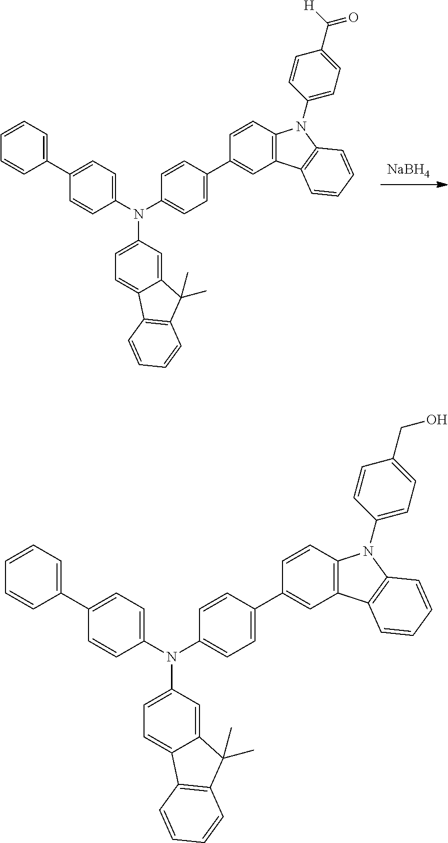 [SMILES: CC1(C)c2ccccc2-c2ccc(N(c3ccc(-c4ccccc4)cc3)c3ccc(-c4ccc5c(c4)c4ccccc4n5-c4ccc(C=O)cc4)cc3)cc21 ; "NaBH4" ; CC1(C)c2ccccc2-c2ccc(N(c3ccc(-c4ccccc4)cc3)c3ccc(-c4ccc5c(c4)c4ccccc4n5-c4ccc(CO)cc4)cc3)cc21]

### Synthesis of (4-(3-(4-([1,1′-biphenyl]-4-yl(9,9-dimethyl-9H-fluoren-2-yl)amino)phenyl)-9H-carbazol-9-yl)phenyl)methanol

A round-bottom flask was charged with Formula 1 (4.36 g, 6.17 mmol, 1.00 equiv) under a blanket of nitrogen. The material was dissolved in 40 mL 1:1 THF:EtOH. borohydride (0.280 g, 7.41 mmol, 1.20 equiv) was added in portions and the material was stirred for 3 hours. The reaction mixture was cautiously quenched with 1M HCl, and the product was extracted with portions of dichloromethane. Combined organic fractions were washed with sat. aq. sodium bicarbonate, dried with MgSO₄ and concentrated to a crude residue. The material was purified by chromatography (hexane/dichloromethane gradient), and gave a white solid product (3.79 g). The product had the following characteristics: ¹H-NMR (500 MHz, CDCl₃): δ 8.35 (s, 1H), 8.19 (dt, J=7.8, 1.1 Hz, 1H), 7.73-7.56 (m, 11H), 7.57-7.48 (m, 2H), 7.48-7.37 (m, 6H), 7.36-7.23 (m, 9H), 7.14 (s, 1H), 4.84 (s, 2H), 1.45 (s, 6H). ¹³C-NMR (126 MHz, CDCl₃): δ 155.13, 153.56, 147.24, 147.02, 146.44, 141.27, 140.60, 140.11, 140.07, 138.94, 136.99, 136.33, 135.06, 134.35, 132.96, 128.73, 128.44, 127.96, 127.76, 127.09, 126.96, 126.79, 126.62, 126.48, 126.10, 125.15, 124.52, 123.90, 123.54, 123.49, 122.46, 120.66, 120.36, 120.06, 119.43, 118.82, 118.33, 109.95, 109.85, 64.86, 46.87, 27.11.

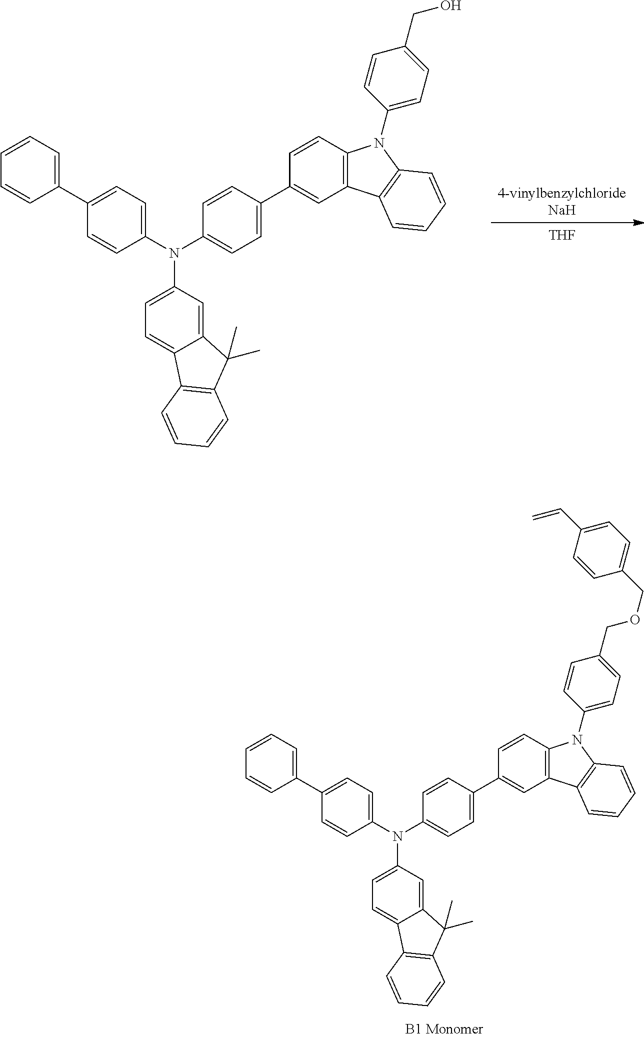

### Synthesis of N-([1,1′-biphenyl]-4-yl)-9,9-dimethyl-N-(4-(9-(4-(((4-vinylbenzyl)oxy)methyl)phenyl)-9H-carbazol-3-yl)phenyl)-9H-fluoren-2-amine (B1 Monomer)

In a nitrogen-filled glovebox, a 100 mL round-bottom flask was charged with Formula 2 (4.40 g, 6.21 mmol, 1.00 equiv) and 35 mL THF. Sodium hydride (0.224 g, 9.32 mmol, 1.50 equiv) was added in portions, and the mixture was stirred for 30 minutes. A reflux condenser was attached, the unit was sealed and removed from the glovebox. 4-vinylbenzyl chloride (1.05 mL, 7.45 mmol, 1.20 equiv) was injected, and the mixture was refluxed until consumption of starting material. The reaction mixture was cooled (iced bath) and cautiously quenched with isopropanol. Sat. aq. NH₄Cl was added, and the product was extracted with ethyl acetate. Combined organic fractions were washed with brine, dried with MgSO₄, filtered, concentrated, and purified by chromatography on silica. The product had the following characteristics: ¹H-NMR (400 MHz, CDCl₃): δ 8.35 (s, 1H), 8.18 (dt, J=7.8, 1.0 Hz, 1H), 7.74-7.47 (m, 14H), 7.47-7.35 (m, 11H), 7.35-7.23 (m, 9H), 7.14 (s, 1H), 6.73 (dd, J=17.6, 10.9 Hz, 1H), 5.76 (dd, J=17.6, 0.9 Hz, 1H), 5.25 (dd, J=10.9, 0.9 Hz, 1H), 4.65 (s, 4H), 1.45 (s, 6H). ¹³C-NMR (101 MHz, CDCl₃): δ 155.13, 153.56, 147.25, 147.03, 146.43, 141.28, 140.61, 140.13, 138.94, 137.64, 137.63, 137.16, 137.00, 136.48, 136.37, 135.06, 134.35, 132.94, 129.21, 128.73, 128.05, 127.96, 127.76, 126.96, 126.94, 126.79, 126.62, 126.48, 126.33, 126.09, 125.14, 124.54, 123.89, 123.54, 123.48, 122.46, 120.66, 120.34, 120.04, 119.44, 118.82, 118.31, 113.92, 110.01, 109.90, 72.33, 71.61, 46.87, 27.11.

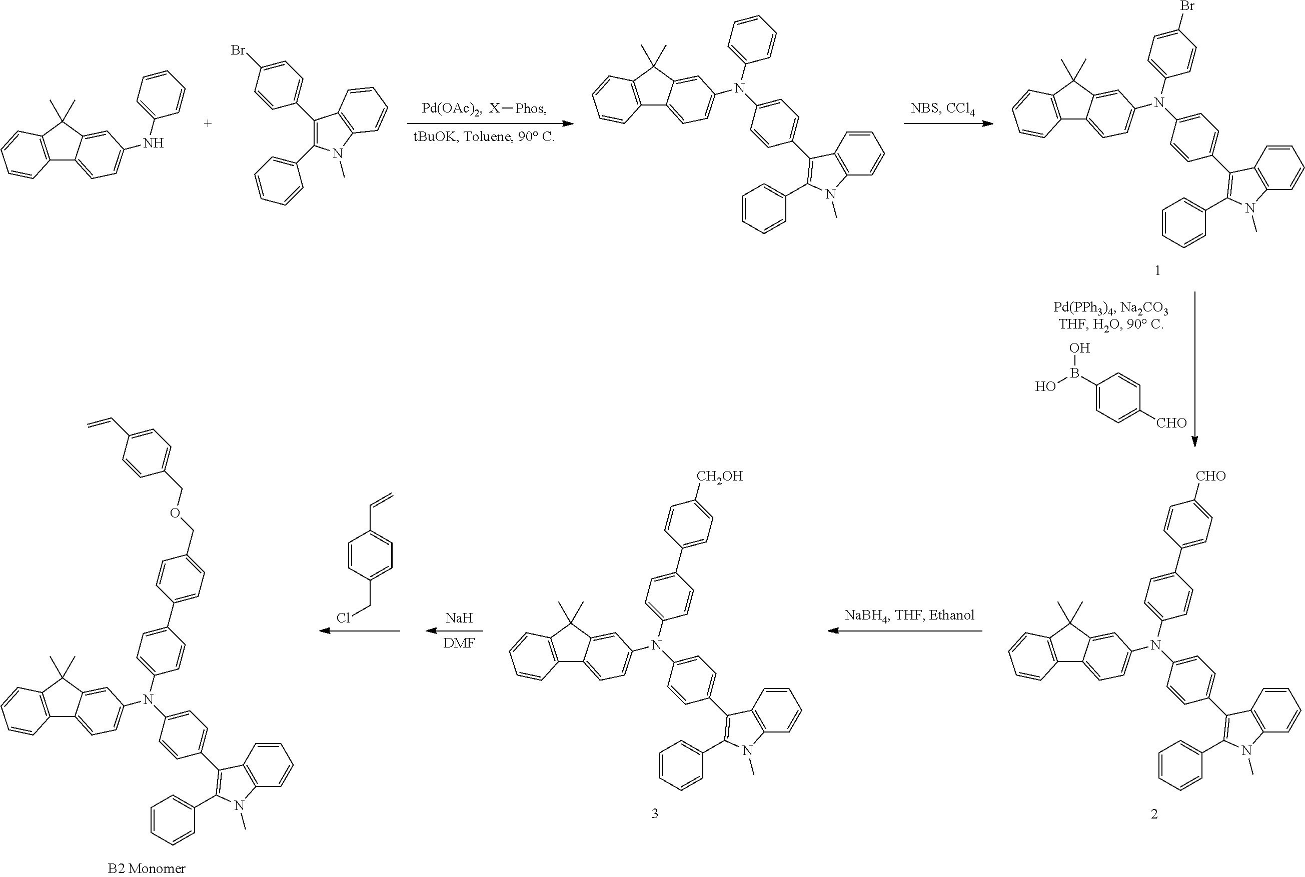

### Synthesis of 4′-((9,9-dimethyl-9H-fluoren-2-yl)(4-(1-methyl-2-phenyl-1H-indol-3-yl)phenyl)amino)-[1,1′-biphenyl]-4-carbaldehyde (2)

A mixture of N-(4-bromophenyl)-9,9-dimethyl-N-(4-(1-methyl-2-phenyl-1H-indol-3-yl)phenyl)-9H-fluoren-2-amine (1) (12.9 g, 20 mmol), (4-formylphenyl) boronic acid (1.07 g, 30 mmol), Pd(PPh₃)₄ (693 mg, 1155, 3%), 2M K₂CO₃ (4.14 g, 30 mmol, 15 mL H2O), and 45 mL of THF was heated at 80° C. under nitrogen atmosphere for 12 h. After cooling to room temperature, the solvent was removed under vacuum and the residue was extracted with dichloromethane. After cooling to room temperature, the solvent was removed under vacuum and then water was added. The mixture was extracted with CH₂Cl₂. The organic layer was collected and dried over anhydrous sodium sulphate. After filtration, the filtrate was evaporated to remove solvent and the residue was purified through column chromatography on silica gel to give light-yellow solid (yield: 75%). MS (ESI): 671.80 [M+H]₊. 1H-NMR (CDCl₃, 400 MHz, TMS, ppm): δ 10.03 (s, 1H), 7.94 (d, 2H), 7.75 (d, 2H), 7.64 (m, 2H), 7.55 (d, 2H), 7.41 (m, 9H), 7.23 (m, 8H), 7.09 (m, 3H), 3.69 (s, 3H), 1.43 (s, 6H).

### Synthesis of (4′-((9,9-dimethyl-9H-fluoren-2-yl)(4-(1-methyl-2-phenyl-1H-indol-3-yl)phenyl)amino)-[1,1′-biphenyl]-4-yl)methanol (3)

To a solution of (2) (10 g 15 mmol) in 50 mL THF and 50 mL ethanol at 40° C., NaBH₄ (2.26 g 60 mmol) was added under nitrogen atmosphere. The solution was allowed to stir at room temperature for 2 h. Then, aqueous hydrochloric acid solution was added until pH 5 and the addition was maintained for a further 30 min. The solvent was removed under vacuum and the residue was extracted with dichloromethane. The product was then obtained by remove of solvent and used for next step without further purification (yield: 95%). MS (ESI): 673.31 [M+H]⁺.

### Synthesis of 9,9-dimethyl-N-(4-(1-methyl-2-phenyl-1H-indol-3-yl)phenyl)-N-(4′-(((4-vinylbenzyl)oxy)methyl)-[1,1′-biphenyl]-4-yl)-9H-fluoren-2-amine (B2 Monomer)

To a solution of (3) (9.0 g, 13.4 mmol) in 50 mL dry DMF was added NaH (482 mg, 20.1 mmol), the mixture was then stirred at room temperature for 1 h. And 4-vinylbenzyl chloride (3.05 g 20.1 mmol) was added to above solution via syringe. The mixture was heated to 50° C. for 24 h. After quenched with water, the mixture was poured into water to remove DMF. The residue was filtrated and the resulting solid was dissolved with dichloromethane, which was then washed with water. The solvent was removed under vacuum and the residue was extracted with dichloromethane. The product was then obtained by column chromatography on silica gel (yield: 90%). MS (ESI): 789.38 [M+H]⁺. 1H-NMR (CDCl₃, 400 MHz, TMS, ppm): δ 7.59 (d, 4H), 7.48 (m, 2H), 7.40 (m, 18H), 7.22 (m, 8H), 6.71 (dd, 1H), 5.77 (d, 1H), 5.25 (d, 1H), 4.58 (s, 4H), 3.67 (s, 3H), 1.42 (s, 6H).

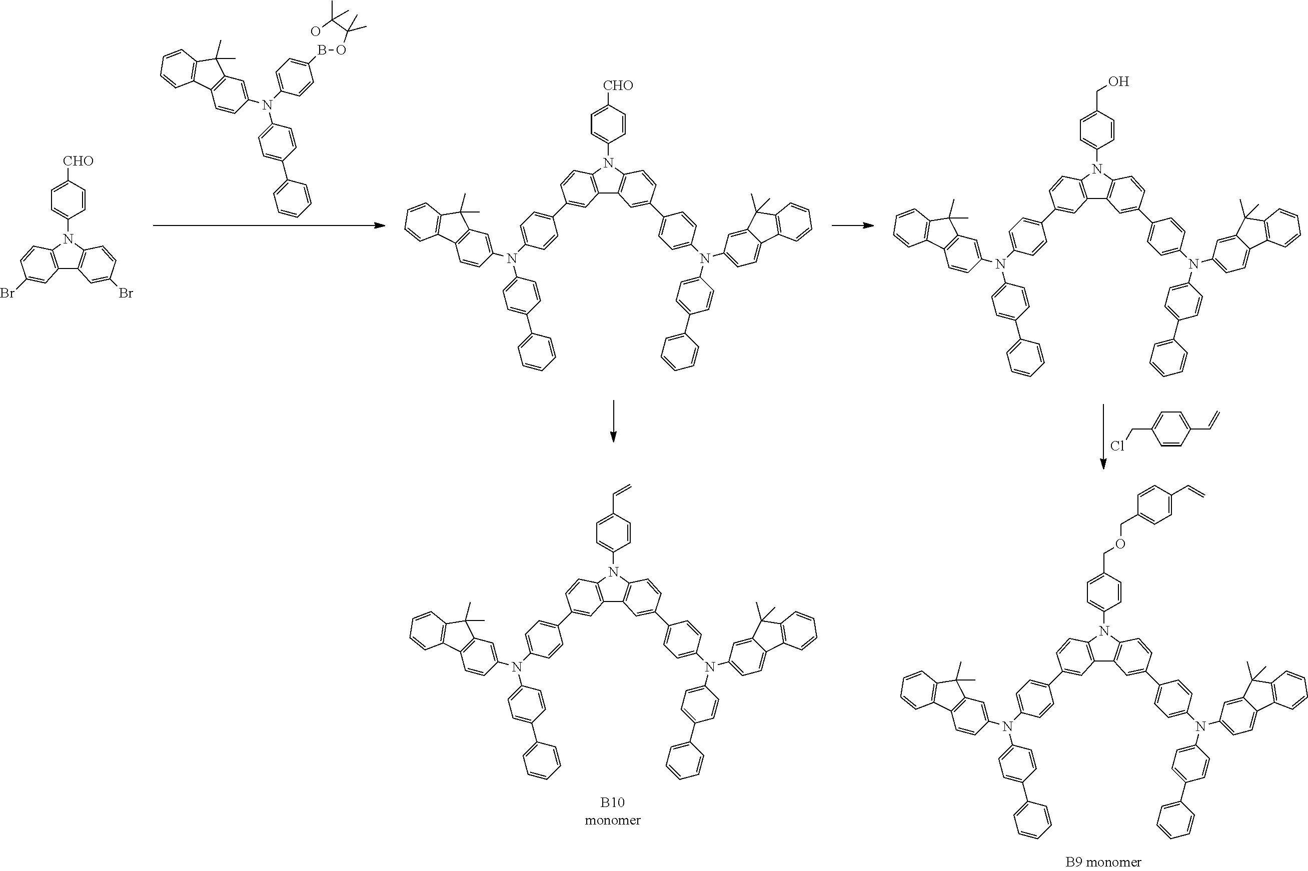

### Synthesis of 4-(3,6-bis(4-([1,1′-biphenyl]-4-yl(9,9-dimethyl-9H-fluoren-2-yl)amino)phenyl)-9H-carbazol-9-yl)benzaldehyde

A mixture of 4-(3,6-dibromo-9H-carbazol-9-yl)benzaldehyde (6.00 g, 17.74 mmol), N-([1,1′-biphenyl]-4-yl)-9,9-dimethyl-N-(4-(4,4,5,5-tetramethyl-1,3,2-dioxaborolan-2-yl)phenyl)-9H-fluoren-2-amine (15.70 g, 35.49 mmol), Pd(PPh3)3 (0.96 g), 7.72 g K2CO3, 100 mL THF and 30 mL H2O was heated at 80° C. under nitrogen overnight. After cooled to room temperature, the solvent was removed under vacuum and the residue was extracted with dichloromethane. The product was then obtained by column chromatography on silica gel with petroleum ether and dichloromethane as eluent, to provide desired product (14.8 g, yield 92%). ¹H NMR (CDCl₃, ppm): 10.14 (s, 1H), 8.41 (d, 2H), 8.18 (d, 2H), 7.86 (d, 2H), 7.71 (dd, 2H), 7.56-7.68 (m, 14H), 7.53 (m, 4H), 7.42 (m, 4H), 7.26-735 (m, 18H), 7.13-7.17 (d, 2H), 1.46 (s 12H).

### (4-(3,6-bis(4-([1,1′-biphenyl]-4-yl(9,9-dimethyl-9H-fluoren-2-yl)amino)phenyl)-9H-carbazol-9-yl)phenyl)methanol

4-(3,6-bis(4-([1,1′-biphenyl]-4-yl(9,9-dimethyl-9H-fluoren-2-yl)amino)phenyl)-9H-carbazol-9-yl)benzaldehyde (10.0 g 8.75 mmol) was dissolved into 80 mL THF and 30 mL ethanol. NaBH₄ (1.32 g 35.01 mmol) was added under nitrogen atmosphere over 2 hours. Then, aqueous hydrochloric acid solution was added until pH 5 and the mixture was kept stirring for 30 min. The solvent was removed under vacuum and the residue was extracted with dichloromethane. The product was then dried under vacuum and used for the next step without further purification.

### Synthesis of B-9 Monomer

0.45 g 60% NaH was added to 100 mL dried DMF solution of 10.00 g of (4-(3,6-bis(4-([1,1′-biphenyl]-4-yl(9,9-dimethyl-9H-fluoren-2-yl)amino)phenyl)-9H-carbazol-9-yl)phenyl)methanol. After stirred at room temperature for 1 h, 2.00 g of 1-(chloromethyl)-4-vinylbenzene was added by syringe. The solution was stirred at 60° C. under N2 and tracked by TLC. After the consumption of the starting material, the solution was cooled and poured into ice water. After filtration and washed with water, ethanol and petroleum ether respectively, the crude product was obtained and dried in vacuum oven at 50° C. overnight and then purified by flash silica column chromatography with grads evolution of the eluent of dichloromethane and petroleum ether (1:3 to 1:1). The crude product was further purified by recrystallization from ethyl acetate and column chromatography which enabled the purity of 99.8%. ESI-MS (m/z, Ion): 1260.5811, (M+H)⁺. ¹H NMR (CDCl₃, ppm): 8.41 (s, 2H), 7.58-7.72 (m, 18H), 7.53 (d, 4H), 7.38-7.50 (m, 12H), 7.25-7.35 (m, 16H), 7.14 (d, 2H), 6.75 (q, 1H), 5.78 (d, 1H), 5.26 (d, 1H), 4.68 (s, 4H), 1.45 (s, 12H).

### Synthesis of B-10 Monomer

Under N₂ atmosphere, PPh₃CMeBr (1.45 g, 4.0 mmol) was charged into a three-neck round-bottom flask equipped with a stirrer, to which 180 mL anhydrous THF was added. The suspension was placed in an ice bath. Then t-BuOK (0.70 g 6.2 mmol) was added slowly to the solution, the reaction mixture turned into bright yellow. The reaction was allowed to react for an additional 3 h. After that, 4-(3,6-bis(4-([1,1′-biphenyl]-4-yl(9,9-dimethyl-9H-fluoren-2-yl)amino)phenyl)-9H-carbazol-9-yl)benzaldehyde (2.0 g, 1.75 mmol) was charged into the flask and stirred at room temperature overnight. The mixture was quenched with 2N HCl, and extracted with dichloromethane, and the organic layer was washed with deionized water three times and dried over anhydrous Na₂SO₄. The filtrate was concentrated and purified on silica gel column using dichloromethane and petroleum ether (1:3) as eluent. The crude product was further recrystallized from dichloromethane and ethyl acetate with purity of 99.8%. ESI-MS (m/z, Ion): 1140.523, (M+H)⁺. ¹H NMR (CDCl₃, ppm): 8.41 (s, 2H), 7.56-7.72 (m, 18H), 7.47-7.56 (m, 6H), 7.37-7.46 (m, 6H), 7.23-7.36 (m, 18H), 6.85 (q, 1H), 5.88 (d, 1H), 5.38 (d, 1H), 1.46 (s, 12H).

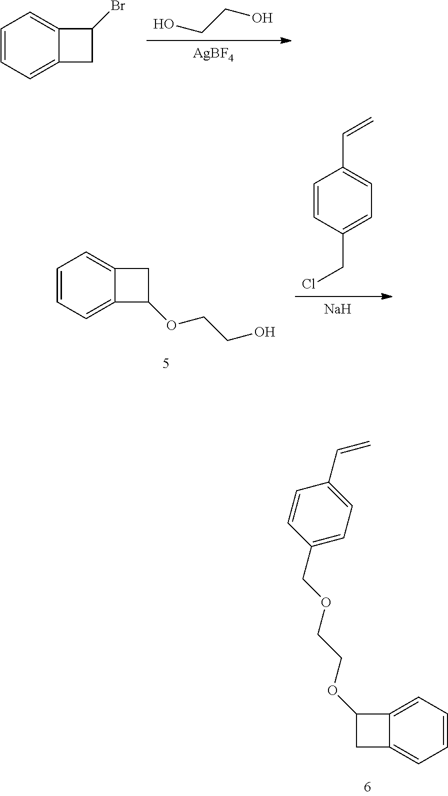

### Synthesis of 2-(bicyclo[4.2.0]octa-1,3,5-trien-7-yloxy)ethan-1-ol (5)

To a 250 mL round bottom flask was added 7-bromobicyclo[4.2.0]octa-1,3,5-triene (10.0 g, 54.6 mmol) and 100 mL ethylene glycol. The biphasic mixture was cooled to 0° C. followed by the slow addition of solid silver(I)tetrafluoroborate (11.7 g, 60.1 mmol) to maintain a temperature about 30° C. After addition, the reaction mixture was stirred at 50° C. for 3 h. Once cooled down to room temperature, 200 ml water and 400 ml ether were added. The resulting mixture was filtered through celite. The organic layer was washed with water 3×300 ml and then dried over Na₂SO₄. After filtration, the filtrate was concentrated and the obtained oil was purified by column chromatography on silica gel to remove the excess ethylene glycol (yield: 70%). MS (ESI): 165.14 [M+H]⁺. ¹H-NMR (CDCl₃, 400 MHz, TMS, ppm): δ 7.28 (m, 3H), 7.14 (d, 1H), 5.08 (t, 1H), 3.76 (t, 2H), 3.72 (m, 2H), 3.44 (d, 1H), 3.11 (d, 1H).

### Synthesis of 7-(2-((4-vinylbenzyl)oxy)ethoxy)bicyclo[4.2.0]octa-1,3,5-triene (6)

To a solution of (5) (3.0 g, 18.3 mmol) in 50 mL dry DMF was added NaH (658 mg, 27.4 mmol), the mixture was stirred at room temperature for 1 h. And 1-(chloromethyl)-4-vinylbenzene (4.18 g, 27.4 mmol) was added to above solution via syringe. The mixture was heated to 60° C. overnight. After quenched with water, the mixture was poured into water to remove DMF. The residue was filtrated and the resulting solid was dissolved with dichloromethane, which was then washed with water. The solvent was removed under vacuum and the residue was extracted with dichloromethane. The product was then obtained by column chromatography on silica gel (yield: 82%). MS (ESI): 281.37 [M+H]⁺. ¹H-NMR (CDCl₃, 400 MHz, TMS, ppm): δ 7.38 (d, 2H), 7.30 (m, 3H), 7.23 (m, 2H), 7.14 (d, 1H), 6.74 (dd, 1H), 5.75 (d, 1H), 5.24 (d, 1H), 5.11 (t, 1H), 4.57 (s, 2H), 3.85 (t, 2H), 3.76 (t, 2H), 3.44 (d, 1H), 3.14 (d, 1H).

### General Protocol for Radical Polymerization of Charge Transporting B Monomers:

In a glovebox, B monomer (1.00 equiv) was dissolved in anisole (electronic grade, 0.25 M). The mixture was heated to 70° C., and AIBN solution (0.20 M in toluene, 5 mol %) was injected. The mixture was stirred until complete consumption of monomer, at least 24 hours (2.5 mol % portions of AIBN solution can be added to complete conversion). The polymer was precipitated with methanol (10× volume of anisole) and isolated by filtration. The filtered solid was rinsed with additional portions of methanol. The filtered solid was re-dissolved in anisole and the precipitation/filtration sequence repeated twice more. The isolated solid was placed in a vacuum oven overnight at 50° C. to remove residual solvent.

Monomer A has the following structure

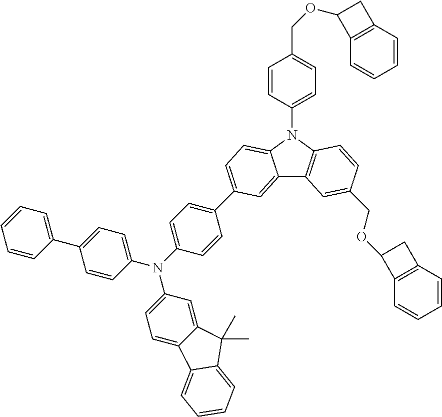 [SMILES: CC1(C)c2ccccc2-c2ccc(N(c3ccc(-c4ccccc4)cc3)c3ccc(-c4ccc5c(c4)c4cc(COC6Cc7ccccc76)ccc4n5-c4ccc(COC5Cc6ccccc65)cc4)cc3)cc21]

Monomer B has the following structure:

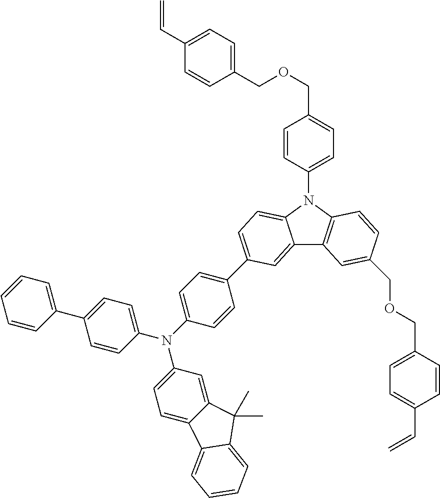 [SMILES: C=Cc1ccc(COCc2ccc(-n3c4ccc(COCc5ccc(C=C)cc5)cc4c4cc(-c5ccc(N(c6ccc(-c7ccccc7)cc6)c6ccc7c(c6)C(C)(C)c6ccccc6-7)cc5)ccc43)cc2)cc1]

Monomer C has the following structure

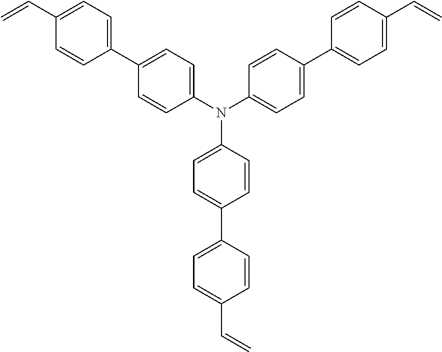 [SMILES: C=Cc1ccc(-c2ccc(N(c3ccc(-c4ccc(C=C)cc4)cc3)c3ccc(-c4ccc(C=C)cc4)cc3)cc2)cc1]

Purity and halide analyses of the anisole and tetralin used in these examples were as follows:

| | purity | halide | | metal | |
|---|---|---|---|---|---|
| anisole | 100% | 0.44 | ppm | 9.85 | ppb |
| tetralin | 100% | <5 | ppm* | <20 | ppb* |

*specification limits

Molecular weights of the polymers were as follows

| polymer | Mₙ | M_{w} | M_{z} | M_{z+1} | PDI |
|---|---|---|---|---|---|
| B1 | 21,501 | 45,164 | 73,186 | 102,927 | 2.10 |
| B2, low MW | 4,606 | 8,233 | 13,254 | 22,789 | 1.79 |
| B2, high Mw | 27,171 | 59,262 | 104,762 | 157,817 | 2.18 |
| B3 | 20,308 | 47,884 | 91,342 | 143,362 | 2.36 |
| B4 | 8,996 | 20,068 | 34,347 | 50,800 | 2.23 |
| B5 | 7,088 | 13,328 | 23,564 | 37,935 | 1.88 |
| B6 | 19,941 | 56,004 | 126,177 | 218,454 | 2.81 |
| B7 | 9,182 | 27,767 | 57,693 | 98,384 | 3.02 |
| B8 | 9,006 | 20,094 | 39,689 | 67,693 | 2.23 |
| B9 | 21,482 | 67,058 | 132,385 | 226,405 | 3.12 |
| B10 | 11,951 | 48,474 | 140,533 | 248,932 | 4.06 |

B-staged charge transporting polymers are formed by step-growth polymerization via [4+2] Diels-Alder reaction between BCB and styrene (Sty) in Monomers A, B & C. The polymers obtained were as follows.

| 105 C./5 hr | 105 C./40 hr | 105 C./5 hr | 105 C./40 hr |
|---|---|---|---|
| B-staged A&B | B-staged A&B | B-staged A& B&C | B-staged A& B&C |
| (A:B = 0.5:0.5 | (A:B = 0.5:0.5 | (A:B:C = 0.525:0.375:0.100 | (A:B:C = 0.525:0.375:0.100 |
| molar ratio) | molar ratio) | molar ratio) | molar ratio) |
| Mₙ = 2,845 Da | Mₙ = 4369 Da | Mₙ = 2,727 Da | Mₙ = 5,672 Da |
| M_{w} = 6,534 Da | M_{w} = 16,618 Da | M_{w} = 7,509 Da | M_{w} = 25,656 Da |
| M_{z} = 41,010 Da | M_{z} = 41,445 Da | M_{z} = 33,321 Da | M_{z} = 65,112 Da |
| M_{z+1} = 422,515 Da | M_{z+1} = 65,079 Da | M_{z+1} = 159,174 Da | M_{z+1} = 100,317 Da |
| PDI = 2.30 | PDI = 3.80 | PDI = 2.75 | PDI = 4.52 |

### General Experimental Procedures for Hole Transporting Layer (HTL) Thermal Cross-Linking and Strip Tests

1) Preparation of HTL formulation solution: Charge transporting B polymer solid powders were directly dissolved into anisole to make a 2 wt % stock solution. In the case of HTL homopolymers, the solution was stirred at 80° C. for 5 to 10 min in N₂ for complete dissolving. Organic acids were directly dissolved into anisole to make a 2 wt % stock solution. In the case of DDSA, the anisole solvent was replaced by 2-heptanone for complete dissolving. An aliquot of 2 wt % add stock solution was added into 2 wt % HTL stock solution to make the HTL formulation with desirable HTL to add weight ratio (HTL:acid=100:0.5, 100:1, 100:2, 100:5 and 100:10 wtwt). The resulting formulation solution was filtered through 0.2 um PTFE syringe filter prior to depositing onto Si wafer. In the case of shelf-stability study, the resulting HTL formulation was prepared using toluene for HTL homopolymer and anisole for B-staged HTL copolymer, sealed in N₂ and then kept in refrigerator for 4 weeks before proceeding to the following thermal cross-inking and strip tests. The use of toluene rather than anisole is expected to accelerate the aging process of the formulation.
2) Preparation of thermally cross-linked HTL polymer film: Si wafer was pre-treated by UV-ozone for 2 to 8 min prior to use. Several drops of the above filtered formulation solution were deposited onto the pre-treated Si wafer. The thin film was obtained by spin coating at 500 rpm for 5 s and then 2000 rpm for 30 s. The resulting film was then transferred into the N₂ purging box. The “wet” film was prebaked at 100° C. for 1 min to remove most of residual anisole. Subsequently, the film was thermally cross-linked at 170° C. for 15 to 60 min or 190° C. for 10 to 60 min or 205° C. for 5 to 60 min or 220° C. for 10 to 20 min.
3) Strip test on thermally cross-linked HTL polymer film: The “Initial” thickness of thermally cross-linked HTL film was measured using an M-2000D ellipsometer (J. A Woollam Co., Inc.). Then, several drops of anisole w added onto the film to form a puddle. After 90 s, the anisole solvent was spun off at 3500 rpm for 30 s. The “Strip” thickness of the film was immediately measured using the ellipsometer. The film was then transferred into the N₂ purging box, followed by post-baking at 100° C. for 1 min to remove any swollen anisole in the film. The “Final” thickness was measured using the ellipsometer. The film thickness was determined using Cauchy model and averaged over 9=3×3 points in a 1 cm×1 cm area. The optical properties (reflective and extinction index) of cross-linked HTL films were analyzed using Gen-Osc model and averaged over 9=3×3 points in a 1 cm×1 cm area.
“−Strip”=“Strip”−“Initial”: Initial film loss due to solvent strip
“−PSB”=“Final”−“Strip”: Further film loss of swelling solvent
“−Total”=“−Strip”+“−PSB”=“Final”−“Initial”: Total film loss due to solvent strip and swelling
   Strip tests were applied for studying thermal cross-linking of HTL polymers in presence of organic acid. For a fully cross-linked HTL film with good solvent resistance, the total film loss after anisole stripping should be <1 nm, preferably <0.5 nm.

### Example 1 Formulation of B1 Homopolymer and HB Acid Catalyst

B1 homopolymer gives almost 100% film loss after 205° C./10 min thermal ti whited indicating the benzyl ether is non-reactive in absence of acid catalyst and no cross-linking occurs.
B1 homopolymer gives significant cross-linking upon the addition of HB acid. The total film loss decreases with increasing HB level and cross-linking temperature and time.
Fully cross-linked B1 homopolymer film with good solvent resistance can be achieved at 5 wt % HB and 190° C./10 min, 2 wt % HB and 205° C./5 min, 1 wt % HB and 205° C./10 min.

TABLE 1
Strip tests of cross-linked B1 + HB films

| | HB level, | | | -Strip | | -PSB | -Total |
|---|---|---|---|---|---|---|---|
| Cross-linking | wt % | Initial (nm) | Strip (nm) | (nm) | Final (nm) | (nm) | (nm) |
| 170 C./15 min | 10 | 35.82 ± 0.03 | 33.23 ± 0.24 | −2.60 | 32.49 ± 0.24 | −0.74 | [symbol] |
| 190 C./10 min | 2 | 37.08 ± 0.04 | 35.02 ± 0.21 | −2.05 | 34.37 ± 0.30 | −0.66 | [symbol] |
| 190 C./10 min | 5 | 36.68 ± 0.29 | 36.23 ± 0.18 | −0.45 | 35.81 ± 0.34 | −0.43 | [symbol] |
| 190 C./20 min | 5 | 37.03 ± 0.04 | 37.27 ± 0.08 | 0.25 | 36.93 ± 0.05 | −0.34 | [symbol] |
| 205/5 min | 2 | 36.69 ± 0.04 | 37.04 ± 0.11 | 0.35 | 36.65 ± 0.03 | −0.39 | [symbol] |
| 205/10 min | 0 | 38.22 ± 0.39 | 1.87 ± 0.19 | −36.35 | 1.82 ± 0.17 | −0.05 | [symbol] |
| 205/10 min | 0.5 | 40.42 ± 0.22 | 36.63 ± 0.29 | −3.80 | 35.92 ± 0.21 | −0.71 | [symbol] |
| 205/10 min | 1 | 36.59 ± 0.15 | 36.44 ± 0.22 | −0.15 | 35.68 ± 0.19 | −0.77 | [symbol] |
| 205/10 min | 2 wt % | 36.83 ± 0.14 | 37.06 ± 0.14 | 0.23 | 36.73 ± 0.11 | − 0.33 | [symbol] |
| 205/10 min | 10 wt % | 38.56 ± 0.39 | 38.86 ± 0.27 | 0.30 | 38.26 ± 0.27 | −0.60 | [symbol] |

### Example 2 Formulation of B1 Homopolymer and TB Acid Catalyst

B1 homopolymer gives almost 100% film loss after 205° C./10 min thermal ti whiled indicating the benzyl ether is non-reactive in absence of acid catalyst and no cross-linking occurs.
B1 homopolymer gives significant cross-linking upon the addition of TB acid. The total film loss decreases with increasing TB level and cross-linking temperature and time.
B1 homopolymer film with good solvent resistance can be achieved at 5 wt % TB and 190° C./5 min, 2 wt % TB and 205° C./5 min.
B1 homopolymer+TB gives similar performance to that of B1 homopolymer+HB

TABLE 2
Strip tests of cross-linked high MW B1 + TB films

| | TB | | | | | | |
|---|---|---|---|---|---|---|---|
| | level, | Initial | Strip | -Strip | Final | -PSB | -Total |
| Cross-linking | wt % | (nm) | (nm) | (nm) | (nm) | (nm) | (nm) |
| 170 C./15 min | 5 | 36.52 ± | 33.70 ± | −2.82 | 32.70 ± | −1.01 | [symbol] |
| | | 0.10 | 0.17 | | 0.17 | | |
| 170 C./15 min | 10 | 35.93 ± | 33.09 ± | −2.84 | 32.46 ± | −0.63 | [symbol] |
| | | 0.10 | 0.74 | | 0.69 | | |
| 190 C./5 min | 5 | 37.63 ± | 37.44 ± | −0.19 | 37.00 ± | −0.44 | [symbol] |
| | | 0.22 | 0.33 | | 0.41 | | |
| 190 C./10 min | 2 | 34.78 ± | 30.99 ± | −3.78 | 30.16 ± | −0.83 | [symbol] |
| | | 0.05 | 0.19 | | 0.28 | | |
| 190 C./10 min | 5 | 36.17 ± | 36.22 ± | 0.06 | 35.89 ± | −0.33 | [symbol] |
| | | 0.08 | 0.10 | | 0.08 | | |
| 205/5 min | 2 | 37.33 ± | 37.44 ± | 0.11 | 37.08 ± | −0.36 | [symbol] |
| | | 0.13 | 0.17 | | 0.23 | | |
| 205/5 min | 5 | 37.58 ± | 37.62 ± | 0.04 | 37.31 ± | −0.30 | [symbol] |
| | | 0.18 | 0.23 | | 0.15 | | |
| 205/10 min | 0 | 38.22 ± | 1.87 ± | −36.35 | 1.82 ± | −0.05 | [symbol] |
| | | 0.39 | 0.19 | | 0.17 | | |
| 205/10 min | 1 | 36.65 ± | 34.41 ± | −2.24 | 33.28 ± | −1.13 | [symbol] |
| | | 0.20 | 0.36 | | 0.21 | | |
| 205/10 min | 2 | 36.59 ± | 36.85 ± | 0.27 | 36.53 ± | −0.32 | [symbol] |
| | | 0.13 | 0.10 | | 0.09 | | |
| 205/10 min | 5 | 36.37 ± | 36.50 ± | 0.13 | 36.20 ± | −0.30 | [symbol] |
| | | 0.10 | 0.09 | | 0.10 | | |
| 205/10 min | 10 | 35.54 ± | 35.71 ± | 0.17 | 35.45 ± | −0.26 | [symbol] |
| | | 0.12 | 0.07 | | 0.11 | | |

### Example 3 Shelf Stability of B1 Homopolymer and TB Formulation

Formulation of B1 homopolymer and TB add that is aged after 29 days still gives fully cross-linked film with good solvent resistance after 205° C./10 min thermal treatment, similar to the performance of the film prayed using flush formulation
B1 homopolymer+TB film prepared using aged formulation and cross-linked at 205° C./10 min still gives identical optical properties to the film prepared using fresh formulation.
The good shelf stability of B1 homopolymer in presence of highly reactive TB add can be attributed to the absence of typical reactive cross-linkable group such as styrene, acrylic etc.

TABLE 3-1
Strip tests of cross-linked B1 homopolymer + TB films prepared from
fresh and aged formulation

| | | | | | | | |
|---|---|---|---|---|---|---|---|
| | TB | | | | | | |
| | level, | Initial | Strip | -Strip | Final | -PSB | -Total |
| Cross-linking | wt% | (nm) | (nm) | (nm) | (nm) | (nm) | (nm) |

Day

[symbol]

| | | | | | | | |
|---|---|---|---|---|---|---|---|
| 205 C./10 min | 10 | 35.54 ± | 35.71 ± | 0.17 | 35.45 ± | −0.26 | [symbol] |
| | | 0.12 | 0.07 | | 0.11 | | |

Day

[symbol]

| | | | | | | | |
|---|---|---|---|---|---|---|---|
| 205 C./10 min | 10 | 36.11 ± | 35.94 ± | −0.17 | 35.43 ± | −0.51 | [symbol] |
| | | 0.07 | 0.13 | | 0.07 | | |

TABLE 3-2
Optical properties of cross-linked B1 homopolymer +
TB films prepared from fresh and aged formulation

| | Day 0 | | Day 29 | |
|---|---|---|---|---|
| Wavelength | Refractive | Extinction | Refractive | Extinction |
| (nm) | Index | Coefficient | Index | Coefficient |
| 227 | 1.8427 | 0.4156 | 1.8501 | 0.4114 |
| 260 | 1.7863 | 0.2784 | 1.7888 | 0.2729 |
| 293 | 1.7606 | 0.2312 | 1.7616 | 0.2259 |
| 351 | 1.8040 | 0.3713 | 1.8004 | 0.3809 |
| 632 | 1.7013 | 0 | 1.7077 | 0 |

### Example 4 Formulation of Low and High MW B2 Homopolymer and HB Acid Catalyst

Low and High MW B2 Homopolymer gives almost 100% film loss after 205° C./10 min thermal treatment, indicating the benzyl ether is non-reactive in absence of acid catalyst and no cross-linking occurs.
Low and High MW B2 Homopolymer gives significant cross-linking upon the addition of HB acid. The total film loss decreases with increasing HB level and cross-linking temperature and time.
Low and High MW B2 Homopolymer film with good solvent resistance can be achieved at 5 wt % HB and 205° C./5 min, 2 wt % HB and 205° C./10 min for low MW polymer, 2 wt % HB and 190° C./10 min, 1 wt % HB and 205° C./10 min for high MW polymer.
High MW B2+HB pedants better than that of low MWB2+HB.

TABLE 4
Skip tests of cross-linked low and high MW B2 Homopolymer + HB films

| | | | | | | | |
|---|---|---|---|---|---|---|---|
| | HB | | | | | | |
| | level, | Initial | Strip | -Strip | Final | -PSB | -Total |
| Cross-linking | wt% | (nm) | (nm) | (nm) | (nm) | (nm) | (nm) |

Low MW B2 homopolymer + HB

| | | | | | | | |
|---|---|---|---|---|---|---|---|
| 190 C./10 min | 5 | 34.56 ± | 31.15 ± | −3.42 | 30.42 ± | −0.73 | [symbol] |
| | | 0.11 | 0.12 | | 0.17 | | |
| 190 C./10 min | 10 | 33.79 ± | 31.17 ± | −2.62 | 30.68 ± | −0.49 | [symbol] |
| | | 0.07 | 0.13 | | 0.27 | | |
| 205 C./5 min | 5 | 33.99 ± | 33.41 ± | −0.58 | 33.19 ± | −0.22 | [symbol] |
| | | 0.06 | 0.09 | | 0.13 | | |
| 205 C./10 min | 0 | 37.46 ± | 1.88 ± | −35.58 | 1.35 ± | −0.54 | [symbol] |
| | | 0.10 | 0.99 | | 0.32 | | |
| 205 C./10 min | 1 | 32.67 ± | 31.27 ± | −1.40 | 30.44 ± | −0.84 | [symbol] |
| | | 0.09 | 0.23 | | 0.13 | | |
| 205 C./10 min | 2 | 33.10 ± | 32.81 ± | −0.29 | 32.55 ± | −0.26 | [symbol] |
| | | 0.15 | 0.26 | | 0.13 | | |
| 205 C./10 min | 5 | 34.36 ± | 34.20 ± | −0.16 | 33.97 ± | −0.23 | [symbol] |
| | | 0.04 | 0.08 | | 0.21 | | |
| 205 C./10 min | 10 | 35.02 ± | 34.45 ± | −0.57 | 34.23 ± | −0.22 | [symbol] |
| | | 0.08 | 0.12 | | 0.04 | | |

High MW B2 homopolymer + HB

| | | | | | | | |
|---|---|---|---|---|---|---|---|
| 190 C./10 min | 2 | 38.57 ± | 38.70 ± | 0.13 | 38.10 ± | −0.60 | [symbol] |
| | | 0.07 | 0.15 | | 0.34 | | |
| 190 C./10 min | 5 | 38.83 ± | 38.68 ± | −0.15 | 38.36 ± | −0.32 | [symbol] |
| | | 0.44 | 0.25 | | 0.10 | | |
| 205 C./10 min | 0 | 40.71 ± | N/A | N/A | 5.97 ± | N/A | [symbol] |
| | | 0.10 | | | 0.78 | | |
| 205 C./10 min | 1 | 39.33 ± | 39.26 ± | −0.07 | 38.76 ± | −0.50 | [symbol] |
| | | 0.05 | 0.26 | | 0.10 | | |
| 205 C./10 min | 2 | 38.53 ± | 38.76 ± | 0.24 | 38.43 ± | −0.33 | [symbol] |
| | | 0.05 | 0.11 | | 0.07 | | |

### Example 5 Formulation of Low and High MW B2 Homopolymer and TB Acid Catalyst

B2 Homopolymer gives almost 100% film loss after 205° C./10 min thermal treatment, indicating the benzyl ether is non-reactive in absence of acid catalyst and no cross-linking occurs.
B2 Homopolymer gives significant cross-linking upon the addition of TB acid. The total film loss decreases with increasing TB level and cross-linking temperature and time.
Fully cross-linked B2 Homopolymer film with good solvent resistance can be achieved at 5 wt % TB and 205° C./5 min for low MW polymer, 2 wt % TB and 190° C./10 min for high MW polymer.
High MW B2 Homopolymer+TB pedants better than that of low MWHTL-SP-28 (1:0)+TB.
B2 Homopolymer+TB gives similar performance to that of B2 Homopolymer+HB.

TABLE 5
Strip tests of cross-linked low and high MW B2 homopolymer + TB films

| | | | | | | | |
|---|---|---|---|---|---|---|---|
| | TB | | | | | | |
| | level, | | | -Strip | | -PSB | -Total |
| Cross-linking | wt% | Initial (nm) | Strip (nm) | (nm) | Final (nm) | (nm) | (nm) |

Low MW B2 homopolymer + TB

| | | | | | | | |
|---|---|---|---|---|---|---|---|
| 170 C./15 min | 10 | 33.89 ± 0.14 | 28.72 ± 0.19 | −4.67 | 28.01 ± 0.13 | −0.71 | [symbol] |
| 190 C./10 min | 5 | 33.14 ± 0.05 | 31.89 ± 0.23 | −1.25 | 31.20 ± 0.26 | −0.69 | [symbol] |
| 190 C./10 min | 10 | 32.73 ± 0.15 | 31.89 ± 0.16 | −0.84 | 31.44 ± 0.11 | −0.45 | [symbol] |
| 205 C./5 min | 5 | 34.12 ± 0.06 | 33.88 ± 0.14 | −0.24 | 33.60 ± 0.10 | −0.27 | [symbol] |
| 205 C./5 min | 10 | 33.52 ± 0.04 | 33.17 ± 0.06 | −0.36 | 32.99 ± 0.06 | −0.18 | [symbol] |
| 205 C./10 min | 0 | 37.46 ± 0.10 | 1.88 ± 0.99 | −35.58 | 1.35 ± 0.32 | −0.54 | [symbol] |
| 205 C./10 min | 2 | 33.55 ± 0.06 | 31.44 ± 0.38 | −2.11 | 31.01 ± 0.48 | −0.44 | [symbol] |
| 205 C./10 min | 5 | 35.34 ± 0.04 | 35.31 ± 0.08 | −0.03 | 35.11 ± 0.05 | −0.20 | [symbol] |
| 205 C./10 min | 10 | 34.64 ± 0.09 | 34.60 ± 0.10 | −0.04 | 34.41 ± 0.10 | −0.19 | [symbol] |

High MW B2 homopolymer + TB

| | | | | | | | |
|---|---|---|---|---|---|---|---|
| 190 C./10 min | 2 | 41.11 ± 0.04 | 40.43 ± 0.19 | −0.68 | 40.51 ± 0.12 | 0.08 | [symbol] |
| 190 C./10 min | 5 | 40.41 ± 0.04 | 40.43 ± 0.19 | 0.02 | 40.07 ± 0.07 | −0.36 | [symbol] |
| 205 C./10 min | 0 | 40.71 ± 0.10 | N/A | N/A | 5.98 ± 0.78 | N/A | [symbol] |
| 205 C./10 min | 2 | 40.14 ± 0.03 | 40.34 ± 0.12 | 0.20 | 40.01 ± 0.09 | −0.34 | [symbol] |
| 205 C./10 min | 5 wt % | 39.47 ± 0.05 | 39.75 ± 0.14 | 0.28 | 39.50 ± 0.06 | −0.24 | [symbol] |

### Example 6 Shelf Stability of Low MW B2 Homopolymer and TB Formulation

Formulation of low MW B2 homopolymer and TB acid that is aged after 29 days still gives nearly fully cross-linked film with good solvent resistance after 205° C. 10 min thermal it whited, similar to the performance of the film prepared using fresh formulation.
The low MW B2 homopolymer+TB film prepared using aged formulation and cross-linked at 205° C./10 min still gives identical optical properties to the film prepared using fresh formulation.
The good shelf stability of low MW B2 homopolymer in presence of highly reactive TB acid can be attributed to the absence of typical reactive cross-linkable group such as styrene, acrylic etc.

TABLE 6-1
Strip tests of cross-linked low MW B2 homopolymer + TB films
prepared from fresh and aged formulalion

| | | | | | | | |
|---|---|---|---|---|---|---|---|
| | TB | | | | | | |
| | level, | Initial | Strip | -Strip | Final | -PSB | -Total |
| Cross-linking | wt% | (nm) | (nm) | (nm) | (nm) | (nm) | (nm) |

Day

[symbol]

| | | | | | | | |
|---|---|---|---|---|---|---|---|
| 205 C./10 min | 10 | 34.64 ± | 34.60 ± | −0.04 | 34.41 ± | −0.19 | [symbol] |
| | | 0.09 | 0.10 | | 0.10 | | |

Day

[symbol]

| | | | | | | | |
|---|---|---|---|---|---|---|---|
| 205 C./10 min | 10 | 30.98 ± | 30.14 ± | −0.84 | 29.83 ± | −0.31 | [symbol] |
| | | 0.13 | 0.15 | | 0.10 | | |

TABLE 6-2
Optical properties of cross-linked B2 homopolymer +
TB films prepared from fresh and aged formulation

| | Day 0 | | Day 29 | |
|---|---|---|---|---|
| Wavelength | Refractive | Extinction | Refractive | Extinction |
| (nm) | Index | Coefficient | Index | Coefficient |
| 227 | 1.8780 | 0.3997 | 1.8888 | 0.3982 |
| 351 | 1.7696 | 0.3072 | 1.7810 | 0.3161 |
| 383 | 1.9351 | 0.1513 | 1.9617 | 0.1531 |
| 632 | 1.6823 | 0 | 1.6999 | 0 |

### Example 7 Formulation of High MW B2 Homopolymer and DDSA Acid Catalyst

Almost 100% film loss for high MW B2 homopolymer after 205° C./10 min thermal treatment, indicating the benzyl ether is non-reactive in absence of acid catalyst and no cross-linking occurs.
High MW B2 homopolymer gives significant cross-linking upon the addition of 10 wt % DDSA add at 205° C./10 min, result in <2 nm total film loss.
High MW B2 homopolymer+DDSA does not perform as good as that of high MW B2 homopolymer +HB or TB, presumably due to the incompatibility between HTL polymer and DDSA

TABLE 7
Strip tests across-linked high MW B2 Homopolymer + DDSA films

| | | | | | | | |
|---|---|---|---|---|---|---|---|
| | DDSA | | | | | | |
| | level, | Initial | | −Strip | | −PSB | −Total |
| Cross-linking | wt % | (nm) | Strip (nm) | (nm) | Final (nm) | (nm) | (nm) |

High MW HTL-B2 homopolymer + DDSA

| | | | | | | | |
|---|---|---|---|---|---|---|---|
| 205C/10 min | 0 | 40.71 ± 0.10 | N/A | N/A | 5.99 ± 0.78 | N/A | [symbol] |
| 205C/10 min | 10 | 35.68 ± 0.15 | 34.70 ± 0.31 | −0.98 | 33.94 ± 0.12 | −0.76 | [symbol] |

### Example 8 Formulation of High MW HTL-B2 Homopolymer and TGA Catalyst

High MW B2 homopolymer gives more than 85% film loss in presence of 10 wt % AVAND TGA at 205° C./10 min, which temperature is significantly lower than TGAs' decomposition temperature.
High MW B2 homopolymer gives significant cross-linking with 6 to 7 nm film loss in presence of 10 wt % AVAND TGA at 250° C./20 min, which temperature is near TGAs' decomposition temperature.
High MW B2 homopolymer+AVAND TGA does not perform as well as high MW B2 homopolymer +HB or TB, presumably due to the TGAs' high decomposition temperature.

TABLE 8
Strip tests of cross-linked high MW B2 homopolymer + AVAND TGA films

| | | | | | | | |
|---|---|---|---|---|---|---|---|
| | TGA | | | | | | |
| | level, | | | −Strip | | −PSB | −Total |
| Cross-linking | wt % | Initial (nm) | Strip (nm) | (nm) | Final (nm) | (nm) | (nm) |

High MW B2 homopolymer + AVAND HT101

| | | | | | | | |
|---|---|---|---|---|---|---|---|
| 205C/10 min | 10 | 37.16 ± 0.09 | 5.53 ± 0.14 | −31.63 | 5.47 ± 0.10 | −0.06 | [symbol] |
| 250C/20 min | 10 | 37.84 ± 0.14 | 32.42 ± 0.75 | −5.42 | 31.69 ± 0.74 | −0.73 | [symbol] |

High MW B2 homopolymer + AVAND HT102

| | | | | | | | |
|---|---|---|---|---|---|---|---|
| 205C/10 min | 10 | 37.21 ± 0.06 | 6.19 ± 0.11 | −31.02 | 6.13± 0.05 | −0.06 | [symbol] |
| 250C/20 min | 10 | 37.64 ± 0.05 | 31.69 ± 0.45 | −5.96 | 31.11 ± 0.49 | −0.57 | [symbol] |

High MW B2 homopolymer + AVAND HT103

| | | | | | | | |
|---|---|---|---|---|---|---|---|
| 205C/10 min | 10 | 37.07 ± 0.06 | 6.17 ± 0.12 | −30.90 | 6.04 ± 0.09 | −0.13 | [symbol] |
| 250C/20 min | 10 | 37.38 ± 0.11 | 30.88 ± 0.41 | −6.50 | 30.26 ± 0.37 | −0.62 | [symbol] |

### Example 9 (Comparative) Formulation of High MW Comp Homopolymer and HB/TB Acid Catalyst

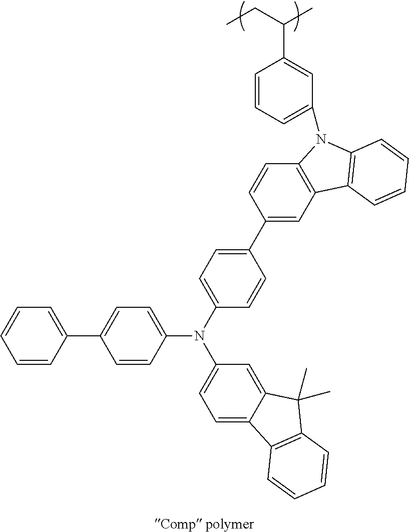 [0073] High MW Comp homopolymer gives more than 60% film loss in presence of 10 wt % HB and TB at 205° C./10 min.
High MW Comp homopolymer +HB/HB gives significantly worse performance than B1, B2 at the same conditions, due to the absence of benzyl ether in Comp Homopolymer.
Benzyloxy functionality is the Key for achieving acid-catalyzed thermal cross-linking.

TABLE 9
Strip tests of cross-linked high MW Comp homopolymer + HB/TB films

| | | | | | | | |
|---|---|---|---|---|---|---|---|
| | HB/TB | | | | | | |
| | level, | Initial | | −Strip | | −PSB | −Total |
| Cross-linking | wt % | (nm) | Strip (nm) | (nm) | Final (nm) | (nm) | (nm) |

High MW Comp homopolymer + HB

| | | | | | | | |
|---|---|---|---|---|---|---|---|
| 205C/10 min | 10 | 40.21 ± 0.06 | 16.04 ± 0.11 | −24.17 | 15.60 ± 0.19 | −0.44 | [symbol] |

High MW Comp homopolymer + TB

| | | | | | | | |
|---|---|---|---|---|---|---|---|
| 205C/10 min | 10 | 40.52 ± 0.05 | 14.25 ± 0.25 | −26.27 | 14.0 ± 0.48 | −0.21 | [symbol] |

### Example 10 Formulation of High MW B3 & B6 Copolymer and TB Acid Catalyst

High MW B3 polymer and B6 polymer gives significant cross-linking after 205° C./10 min thermal treatment due to the BCB self-reaction in absence of acid catalyst B6 is already fully cross-linked with total film loss close to 1 nm
High MW B3 polymer and B6 polymer gives further enhanced cross-linking upon the addition of TB acid. The total film loss further decreases with increasing TB level and cross-linking temperature and time.
Fully cross-linked B3 or B6 film with good solvent resistance can be achieved at 10 wt % TB and 170° C./15 min, 2 wt % TB and 190° C./10 min for B3; 5 wt % TB and 170° C./15 min, 2 wt % TB and 190° C./10 min for B6.
High MW B3 polymer and B6 polymer+TB performs better than that of B1 homopolymer, due to the additional acid catalyzed benzyloxy cross-linking.

TABLE 10
Strip tests across-linked high MW B3 & B6 Copolymer + TB films

| | | | | | | | |
|---|---|---|---|---|---|---|---|
| | TB | | | | | | |
| | level, | Initial | | −Strip | | −PSB | −Total |
| Cross-linking | wt % | (nm) | Strip (nm) | (nm) | Final (nm) | (nm) | (nm) |

High MW B3 polymer + TB

| | | | | | | | |
|---|---|---|---|---|---|---|---|
| 170C/15 min | 2 | 37.40 ± 0.09 | 36.20 ± 0.19 | −1.20 | 35.57 ± 0.08 | −0.63 | [symbol] |
| 170C/15 min | 5 | 36.89 ± 0.11 | 36.20 ± 0.35 | −0.69 | 35.73 ± 0.13 | −0.47 | [symbol] |
| 170C/15 min | 10 | 36.07 ± 0.06 | 35.96 ± 0.09 | −0.11 | 35.65 ± 0.06 | −0.31 | [symbol] |
| 190C/10 min | 2 | 36.60 ± 0.07 | 36.34 ± 0.22 | −0.26 | 36.17 ± 0.07 | −0.17 | [symbol] |
| 190C/10 min | 10 | 35.51 ± 0.03 | 35.73 ± 0.12 | 0.22 | 35.47 ± 0.05 | −0.26 | [symbol] |
| 205C/10 min | 0 | 37.93 ± 0.05 | 37.12 ± 0.18 | −0.81 | 36.42 ± 0.19 | −0.70 | [symbol] |
| 205C/10 min | 2 | 36.36 ± 0.08 | 35.76 ± 0.25 | −0.60 | 35.43 ± 0.21 | −0.33 | [symbol] |
| 205C/10 min | 10 | 35.53 ± 0.12 | 35.77 ± 0.08 | 0.24 | 35.50 ± 0.08 | −0.27 | [symbol] |

High MW HTL-B6 polymer + TB

| | | | | | | | |
|---|---|---|---|---|---|---|---|
| 170C/15 min | 2 | 35.01 ± 0.32 | 34.13 ± 0.22 | −0.88 | 33.68 ± 0.35 | −0.45 | [symbol] |
| 170C/15 min | 5 | 37.07 ± 0.06 | 36.93 ± 0.13 | −0.14 | 36.60 ± 0.15 | −0.33 | [symbol] |
| 170C/15 min | 10 | 33.63 ± 0.22 | 33.71 ± 0.35 | 0.08 | 33.46 ± 0.20 | −0.25 | [symbol] |
| 190C/10 min | 2 | 34.31 ± 0.04 | 34.08 ± 0.07 | −0.23 | 33.81 ± 0.09 | −0.27 | [symbol] |
| 205C/10 min | 0 | 33.32 ± 0.07 | 32.96 ± 0.12 | −0.36 | 32.42 ± 0.10 | −0.54 | [symbol] |
| 205C/10 min | 2 | 34.12 ± 0.04 | 33.66 ± 0.15 | −0.46 | 33.29 ± 0.11 | −0.37 | [symbol] |
| 205C/10 min | 10 | 31.46 ± 0.06 | 31.64 ± 0.10 | 0.18 | 31.34 ± 0.10 | −0.30 | [symbol] |

### Example 11 Formulation of Medium MW B4 & B7 Copolymer and TB Acid Catalyst

Medium MW B4 and B7 gives cross-linking after 205° C./5 to 20 min and 220° C./10 to 20 min thermal treatment due to the BCB self-reaction in absence of acid catalyst. However, the cross-linking is not good enough to give fully cross-linked film, resulting in >10 nm and >4 nm film loss for B4 and B7, respectively.
Medium MW B4 and B7 give significantly improved cross-linking upon the addition of 10 wt % TB acid.
Fully cross-linked film with good solvent resistance can be achieved at 10 wt % TB and 205° C./5 min, for both B4 and B7.
Medium MW B4 and B7+TB performs better than that of B2 copolymer only, due to the additional add catalyzed benzyl ether cross-linking

TABLE 11
Strip tests of cross-linked medium MW B4 and B7 + TB films

| | | | | | | | |
|---|---|---|---|---|---|---|---|
| | TB | | | | | | |
| | level, | Initial | | −Strip | | −PSB | −Total |
| Cross-linking | wt % | (nm) | Strip (nm) | (nm) | Final (nm) | (nm) | (nm) |

Medium MW B4 + TB

| | | | | | | | |
|---|---|---|---|---|---|---|---|
| 205C/5 min | 0 | 40.84 ± 0.22 | 30.30 ± 0.16 | −10.54 | 29.74 ± 0.10 | −0.56 | [symbol] |
| 205C/10 min | 0 | 40.78 ± 0.20 | 30.55 ± 0.13 | −10.23 | 30.02 ± 0.13 | −0.53 | [symbol] |
| 205C/20 min | 0 | 40.82 ± 0.05 | 29.03 ± 0.23 | −11.79 | 28.67 ± 0.18 | −0.36 | [symbol] |
| 205C/5 min | 10 | 38.55 ± 0.07 | 38.48 ± 0.11 | −0.07 | 38.23 ± 0.08 | −0.25 | [symbol] |
| 205C/10 min | 10 | 38.17 ± 0.02 | 38.23 ± 0.10 | 0.06 | 38.00 ± 0.04 | −0.23 | [symbol] |

Medium MW B7 + TB

| | | | | | | | |
|---|---|---|---|---|---|---|---|
| 205C/5 min | 0 | 39.50 ± 0.24 | 36.38 ± 0.19 | −3.12 | 35.68 ± 0.27 | −0.70 | [symbol] |
| 205C/10 min | 0 | 39.84 ± 0.08 | 36.67 ± 0.16 | −3.17 | 35.98 ± 0.14 | −0.69 | [symbol] |
| 205C/20 min | 0 | 39.58 ± 0.17 | 35.94 ± 0.26 | −3.64 | 35.18 ± 0.17 | −0.76 | [symbol] |
| 220C/10 min | 0 | 39.11 ± 0.10 | 34.85 ± 0.12 | −4.26 | 34.15 ± 0.14 | −0.70 | [symbol] |
| 220C/20 min | 0 | 38.77 ± 0.10 | 33.74 ± 0.25 | −5.03 | 33.16 ± 0.16 | −0.58 | [symbol] |
| 205C/5 min | 10 | 36.58 ± 0.12 | 36.61 ± 0.08 | 0.03 | 36.38 ± 0.12 | −0.23 | [symbol] |
| 205C/10 min | 10 | 36.38 ± 0.08 | 36.39 ± 0.13 | 0.01 | 36.08 ± 0.11 | −0.31 | [symbol] |

### Example 12 Formulation of Medium MW B5 & B8 Copolymer and TB Acid Catalyst

Medium MW B8 gives cross-linking after 205° C./5 to 20 min thermal treatment due to the BCB self-reaction in absence of acid catalyst. However, the cross-linking is not good enough to give fully cross-linked film, resulting in >5 nm film loss. Under the same conditions, medium MW B5 gives no cross-linking, resulting in almost 100% film loss.
Medium MW B8 and B5 give significantly improved cross-linking upon the addition of 10 wt % TB acid
Fully cross-linked film with good solvent resistance can be achieved at 10 wt % TB and 190° C./15 min for B8; 10 wt % TB and 205° C./20 min for B5.
Medium MW B8 and B5+TB performs better than that of B1 polymer only, due to the additional acid catalyzed benzyl ether cross-linking

TABLE 12
Strip tests of cross-linked medium MW B5 & B8 + TB films

| | | | | | | | |
|---|---|---|---|---|---|---|---|
| | TB | | | | | | |
| | level | | | −Strip | | −PSB | −Total |
| Cross-linking | wt % | Initial (nm) | Strip (nm) | (nm) | Final (nm) | (nm) | (nm) |

Medium MW B5 + TB

| | | | | | | | |
|---|---|---|---|---|---|---|---|
| 205C/10 min | 0 | 37.74 ± 0.23 | 3.54 ± 0.05 | −4.20 | 3.51 ± 0.07 | −0.03 | [symbol] |
| 205C/20 min | 0 | 38.01 ± 0.39 | 3.63 ± 0.06 | −34.38 | 3.60 ± 0.06 | −0.03 | [symbol] |
| 205C/40 min | 0 | 37.84 ± 0.22 | 3.61 ± 0.06 | −34.23 | 3.59 ± 0.05 | −0.02 | [symbol] |
| 205C/10 min | 10 | 34.14 ± 0.05 | 32.67 ± 0.13 | −1.47 | 32.37 ± 0.12 | −0.30 | [symbol] |
| 205C/20 min | 10 | 34.54 ± 0.05 | 33.73 ± 0.16 | −0.81 | 33.51 ± 0.16 | −0.22 | [symbol] |
| 205C/40 min | 10 | 34.19 ± 0.10 | 33.61 ± 0.08 | −0.58 | 33.44 ± 0.11 | −0.17 | [symbol] |

Medium MW B8 + TB

| | | | | | | | |
|---|---|---|---|---|---|---|---|
| 205C/10 min | 0 | 37.66 ± 0.15 | 29.91 ± 0.22 | −7.75 | 29.41 ± 0.31 | −0.50 | [symbol] |
| 205C/20 min | 0 | 38.33 ± 0.66 | 32.83 ± 0.69 | −5.50 | 32.12 ± 0.84 | −0.71 | [symbol] |
| 205C/40 min | 0 | 37.31 ± 0.11 | 33.00 ± 0.25 | −4.31 | 32.28 ± 0.16 | −0.72 | [symbol] |
| 170C/15 min | 10 | 33.42 ± 0.11 | 30.14 ± 0.13 | −3.28 | 29.57 ± 0.13 | −0.57 | [symbol] |
| | wt % | | | | | | |
| 170C/30 min | 10 | 34.52 ± 0.14 | 31.37 ± 0.16 | −3.15 | 30.80 ± 0.29 | −0.57 | [symbol] |
| | wt % | | | | | | |
| 170C/60 min | 10 | 33.34 ± 0.08 | 31.16 ± 0.16 | −2.18 | 30.57 ± 0.12 | −0.59 | [symbol] |
| | wt % | | | | | | |
| 190C/15 min | 10 | 32.04 ± 0.19 | 31.42 ± 0.19 | −0.62 | 31.12 ± 0.34 | −0.30 | [symbol] |
| | wt % | | | | | | |
| 190C/30 min | 10 | 31.55 ± 0.03 | 31.24 ± 0.06 | −0.31 | 30.93 ± 0.05 | −0.31 | [symbol] |
| | wt % | | | | | | |
| 190C/60 min | 10 | 31.55 ± 0.23 | 31.40 ± 0.20 | −0.15 | 31.16 ± 0.16 | −0.24 | [symbol] |
| | wt % | | | | | | |
| 205C/10 min | 10 | 34.00 ± 0.06 | 34.04 ± 0.10 | 0.04 | 33.71 ± 0.15 | −0.33 | [symbol] |
| | wt % | | | | | | |
| 205C/20 min | 10 | 35.01 ± 0.19 | 35.18 ± 0.16 | 0.17 | 34.95 ± 0.14 | −0.23 | [symbol] |
| | wt % | | | | | | |
| 205C/40 min | 10 | 34.66 ± 0.15 | 34.94 ± 0.11 | 0.28 | 34.71 ± 0.26 | −0.23 | [symbol] |
| | wt % | | | | | | |

### Example 13 Formulation of High MW B9 Homopolymer and HB Acid Catalyst

B9 homopolymer gives almost 100% film loss after 190 C to 220° C./10 min thermal ti whiled, indicating the benzyl ether is non-reactive in absence of acid catalyst and no cross-linking occurs.
B9 homopolymer gives significant cross-linking upon the addition of HB acid. The total film loss decreases with increasing HB level and cross-linking temperature and time.
Fully cross-linked B1 homopolymer film with good solvent resistance can be achieved at 5 wt % HB and 205° C./10 min, 2 wt % HB and 220° C./10 min.

TABLE 13
Strip tests of cross-linked high MW B9 + HB films

| | HB | | | | | | |
|---|---|---|---|---|---|---|---|
| | level, | | | -Strip | | −PSB | −Total |
| Cross-linking | wt % | Initial (nm) | Strip (nm) | (nm) | Final (nm) | (nm) | (nm) |
| 190C/10 min | 0 | 40.78 ± 0.10 | 2.16 ± 0.79 | −38.62 | N/A | N/A | [symbol] |
| 190C/10min | 2 | 45.18 ± 0.21 | 18.64 ± 0.97 | −26.55 | 18.42 ± 0.66 | −0.21 | [symbol] |
| 190C/10 min | 5 | 40.13 ± 0.06 | 36.75 ± 0.25 | −3.38 | 35.91 ± 0.05 | −0.84 | [symbol] |
| 190C/10 min | 10 | 39.35 ± 0.17 | 35.81 ± 0.23 | −3.54 | 35.08 ± 0.27 | −0.74 | [symbol] |
| 205C/10 min | 0 | 40.99 ± 0.05 | 2.16 ± 0.20 | −38.83 | N/A | N/A | [symbol] |
| 205C/10 min | 2 | 40.59 ± 0.14 | 35.48 ± 0.26 | −5.11 | 34.58 ± 0.34 | −0.90 | [symbol] |
| 205C/10 min | 5 | 38.87 ± 0.38 | 38.38 ± 0.29 | −0.48 | 38.14 ± 0.05 | −0.24 | [symbol] |
| 205C/10 min | 10 | 38.21 ± 0.09 | 37.45 ± 0.26 | −0.75 | 37.18 ± 0.05 | −0.27 | [symbol] |
| 220C/10 min | 0 | 42.01 ± 0.48 | 3.31 ± 0.19 | −38.70 | N/A | N/A | [symbol] |
| 220C/10 min | 2 | 41.84 ± 0.04 | 41.39 ± 0.15 | −0.45 | 40.90 ± 0.13 | −0.49 | [symbol] |
| 220C/10 min | 5 | 40.71 ± 0.11 | 40.62 ± 0.30 | −0.10 | 40.32 ± 0.32 | −0.30 | [symbol] |
| 220C/10 min | 10 | 39.14 ± 0.19 | 38.92 ± 0.22 | −0.21 | 38.61 ± 0.17 | −0.31 | [symbol] |

### Example 14 Formulation of Medium MW B10 Copolymer and HB Acid Catalyst

B10 copolymer gives almost 100% film loss after 190 C to 220° C./10 min thermal treatment, indicating the benzyl ether is non-reactive in absence of acid catalyst and no cross-linking occurs.
B10 copolymer gives significant cross-linking upon the addition of HB acid. The total film loss decreases with increasing HB level and cross-linking temperature and time.
Fully cross-linked B10 copolymer film with good solvent resistance can be achieved at 5 wt % HB and 190° C./10 min, 2 wt % HB and 205° C./10 min, 1 wt % HB and 220° C./10 min.

TABLE 14
Strip tests of cross-linked high MW B9 + HB films

| | HB | | | | | | |
|---|---|---|---|---|---|---|---|
| | level, | | | −Strip | | −PSB | −Total |
| Cross-linking | wt % | Initial (nm) | Strip (nm) | (nm) | Final (nm) | (nm) | (nm) |
| 190C/10min | 0 | 41.70 ± 0.19 | 2.85 ± 0.14 | -38.85 | N/A | N/A | [symbol] |
| 190C/10min | 2 | 43.34 ± 0..06 | 40.95 ± 0.31 | −2.40 | 39.88 ± 0.12 | −1.07 | [symbol] |
| 190C/10min | 5 | 42.33 ± 0.27 | 42.92 ± 0.31 | +0.59 | 42.37 ± 0.07 | −0.55 | [symbol] |
| 190C/10min | 0 | 42.81 ± 0.09 | 2.99 ± 0.10 | −39.82 | N/A | N/A | [symbol] |
| 205C/10min | 0.5 | 44.02 ± 0.09 | 24.73 ± 3.39 | −19.29 | 25.31 ± 0.55 | +0.57 | [symbol] |
| 205C/10min | 1 | | | | | | |
| 205C/10min | 2 | 42.90 ± 0.14 | 43.36 ± 0.13 | +0.46 | 4312 ± 0.31 | −0.24 | [symbol] |
| 205C/10min | 5 | 41.72 ± 0.07 | 42.19 ± 0.11 | +0.47 | 41.88 ± 0.13 | −0.31 | [symbol] |
| 220C/10min | 0 | 43.92 ± 0.08 | 3.51 ± 0.23 | −40.41 | N/A | N/A | [symbol] |
| 220C/10min | 0.5 | 43.30 ± 0.22 | 25.70 ± 2.47 | −17.60 | 26.59 ± 3.24 | +0.90 | [symbol] |
| 220C/10min | 1 | 43.13 ± 0.12 | 43.29 ± 0.26 | +0.16 | 42.74 ± 0.23 | −0.55 | [symbol] |
| 220C/10min | 2 | 42.60 ± 0.26 | 42.87 ± 0.18 | +0.27 | 42.55 ± 0.36 | −0.32 | [symbol] |

### Example 15 Formulation of B-Staged Monomers A, B & C and TB Acid Catalyst

B-staged A, B & C give cross-linking after 205° C./5 to 20 min thermal treatment due to the combined BCB and styrene reactions in absence of add catalyst. However, the cross-linking is not good enough to give fully cross-linked film, resulting in 4 to 7 nm loss for those B-staged at 105° C. for 5 hr and >10 nm loss for those B-staged at 105° C. for 40 hr.
B-staged A, B & C gives significantly improved cross-linking upon the addition of 5 or 10 wt % TB acid
Fully cross-linked B-staged A, B & C films with good solvent resistance can only be achieved at 10 wt % TB and 205° C./10 min for 105° C./5 hr B-staged polymers. As for 105° C./40 hr B-staged polymers, the film loss is slightly more than 1 nm at 5 wt % TB and 205° C./20 min, indicating neatly fully cross-linked films.
B-staged A, B & C+TB performs better than those of B-staged copolymer only, due to the additional acid catalyzed benzyl ether cross-linking.

TABLE 15
Strip tests of cross-linked 13-staged Monomers A, B & C + TB films

| | | | | | | | |
|---|---|---|---|---|---|---|---|
| | TB | | | | | | |
| | level, | | | −Strip | | −PSB | −Total |
| Cross-linking | wt % | Initial (nm) | Strip (nm) | (nm) | Final (nm) | (nm) | (nm) |

105C 5 hr B-staged A& B + TB

| | | | | | | | |
|---|---|---|---|---|---|---|---|
| 205C/5 min | 0 | 30.57 ± 0.08 | 25.04 ± 0.10 | −5.53 | 24.53 ± 0.13 | −0.51 | [symbol] |
| 205C/10 min | 0 | 29.94 ± 0.16 | 24.48 ± 0.12 | −5.46 | 24.11 ± 0.15 | −0.37 | [symbol] |
| 205C/20 min | 0 | 30.40 ± 0.25 | 24.04 ± 0.26 | −6.36 | 23.63 ± 0.30 | −0.41 | [symbol] |
| 205C/5 min | 10 | 28.64 ± 0.16 | 27.80 ± 0.15 | −0.84 | 27.30 ± 0.12 | −0.50 | [symbol] |
| 205C/10 min | 10 | 28.28 ± 0.04 | 27.88 ± 0.11 | −0.40 | 27.57 ± 0.08 | −0.31 | [symbol] |
| 205C/20 min | 10 | 28.02 ± 0.07 | 27.84 ± 0.08 | −0.18 | 27.35 ± 0.08 | −0.49 | [symbol] |

105C 5 hr B-staged A, B & C + TB

| | | | | | | | |
|---|---|---|---|---|---|---|---|
| 205C/5 min | 0 | 29.76 ± 0.13 | 26.26 ± 0.18 | −3.50 | 25.78 ± 0.14 | −0.48 | [symbol] |
| 205C/10 min | 0 | 29.81 ± 0.18 | 26.33 ± 0.14 | −3.48 | 25.86 ± 0.16 | −0.47 | [symbol] |
| 205C/20 min | 0 | 29.79 ± 0.07 | 26.46 ± 0.20 | −3.33 | 25.92 ± 0.19 | −0.54 | [symbol] |
| 205C/5 min | 10 | 28.69 ± 0.05 | 27.82 ± 0.13 | −0.87 | 27.47 ± 0.05 | −0.35 | [symbol] |
| 205C/10 min | 10 | 28.19 ± 0.09 | 27.73 ± 0.07 | −0.46 | 27.41 ± 0.08 | −0.32 | [symbol] |
| 205C/20 min | 10 | 27.96 ± 0.08 | 27.73 ± 0.09 | −0.23 | 27.34 ± 0.08 | −0.39 | [symbol] |

105C 40 hr B-staged A & B + TB

| | | | | | | | |
|---|---|---|---|---|---|---|---|
| 205C/5 min | 0 | 25.12 ± 0.32 | 12.79 ± 0.22 | −12.33 | 12.55 ± 0.46 | −0.24 | [symbol] |
| 205C/10 min | 0 | 24.92 ± 0.08 | 13.37 ± 0.43 | −11.55 | 12.80 ± 0.44 | −0.57 | [symbol] |
| 205C/20 min | 0 | 24.73 ± 0.06 | 13.22 ± 0.47 | −11.51 | 12.90 ± 0.31 | −0.32 | [symbol] |
| 205C/5 min | 5 | 25.79 ± 0.19 | 23.69 ± 0.11 | −2.10 | 23.47 ± 0.20 | −0.22 | [symbol] |
| 205C/10 min | 5 | 25.21 ± 0.11 | 23.80 ± 0.08 | −1.41 | 23.65 ± 0.14 | −0.15 | [symbol] |
| 205C/20 min | 5 | 25.20 ± 0.18 | 24.18 ± 0.19 | −1.02 | 23.92 ± 0.11 | −0.26 | [symbol] |

105C 40 hr B-staged A, B & C + TB

| | | | | | | | |
|---|---|---|---|---|---|---|---|
| 205C/5 min | 0 | 27.37 ± 0.13 | 16.94 ± 0.26 | −10.43 | 16.77 ± 0.26 | −0.17 | [symbol] |
| 205C/10 min | 0 | 26.87 ± 0.09 | 16.77 ± 0.18 | −10.10 | 16.49 ± 0.37 | −0.28 | [symbol] |
| 205C/20 min | 0 | 26.98 ± 0.09 | 16.62 ± 0.23 | −10.36 | 16.49 ± 0.27 | −0.13 | [symbol] |
| 205C/5 min | 5 | 27.15 ± 0.39 | 23.84 ± 0.48 | −3.31 | 23.61 ± 0.52 | −0.23 | [symbol] |
| 205C/10 min | 5 | 26.80 ± 0.12 | 24.77 ± 0.23 | −2.03 | 24.48 ± 0.19 | −0.29 | [symbol] |
| 205C/20 min | 5 | 26.84 ± 0.05 | 25.40 ± 0.19 | −1.44 | 25.20 ± 0.09 | −0.20 | [symbol] |

### Example 16 Formulation of B-Staged Monomers A, B & C and HB Acid Catalyst

B-staged A, B & C gives cross-linking after 205° C./5 to 20 min thermal treatment due to the combined BCB and styrene reactions in absence of add catalyst. However, the cross-linking is not good enough to give fully cross-linked film, resulting in about 4 nm loss.
B-staged A, B & C gives significantly improved cross-linking upon the addition of 8.2 wt % HB add at 205° C. for >20 min.
Fully cross-linked B-staged A, B & C film with good solvent resistance can only be achieved at 8.2 wt % HB and 205° C./40 min, 82 wt % HB and 220° C./10 min.
B-staged A, B & C+HB performs better than those of B-staged copolymer only, due to the additional acid catalyzed benzyl ether cross-linking.

TABLE 16
Strip tests of cross-linked B-staged A, B & C + HB films

| | HB | | | | | | |
|---|---|---|---|---|---|---|---|
| | level, | | | −Strip | | −PSB | −Total |
| Cross-linking | wt % | Initial (nm) | Strip (nm) | (nm) | Final (nm) | (nm) | (nm) |
| 205C/5 min | 0 | 29.76 ± 0.13 | 26.26 ± 0.18 | −3.50 | 25.78 ± 0.14 | −0.48 | [symbol] |
| 205C/10 min | 0 | 29.81 ± 0.18 | 26.33 ± 0.14 | −3.48 | 25.86 ± 0.16 | −0.47 | [symbol] |
| 205C/20 min | 0 | 29.79 ± 0.07 | 26.46 ± 0.20 | −3.33 | 25.92 ± 0.19 | −0.54 | [symbol] |
| 205C/10 min | 8.2 | 38.12 ± 0.18 | 32.38 ± 0.35 | −5.73 | 31.76 ± 0.26 | −0.62 | [symbol] |
| 205C/20 min | 8.2 | 35.89 ± 0.03 | 34.41 ± 0.18 | −1.48 | 33.90 ± 0.04 | −0.50 | [symbol] |
| 205C/40 min | 8.2 | 37.39 ± 0.03 | 37.30 ± 0.12 | −0.09 | 36.69 ± 0.02 | −0.61 | [symbol] |
| 205C/60 min | 8.2 | 36.68 ± 0.06 | 36.61 ± 0.14 | −0.06 | 36.15 ± 0.05 | −0.47 | [symbol] |
| 220C/10 min | 8.2 | 37.35 ± 0.03 | 37.46 ± 0.13 | −0.12 | 37.05 ± 0.04 | −0.41 | [symbol] |
| 220C/20 min | 8.2 | 36.13 ± 0.04 | 36.29 ± 0.11 | 0.16 | 35.87 ± 0.04 | −0.43 | [symbol] |

### Example 17 Shelf Stability of B-staged A, B & C and TB Formulation

Formulations of B-staged A, B & C and TB add that are aged after 31 days give nearly 100% film loss after 205° C. 10 min thermal treatment, significantly worse than the performance of the films prepared using fresh formulation.
The poor shelf stability of B-staged A, B & C in presence of highly reactive TB acid can be attributed to residual reactive styrene group from Monomer B and C repeating units.
B3, B4, B6 & B7 homopolymers are more advantageous for shelf-stability due to high stability of benzyl ether and absence of reactive cross-linkable groups.

TABLE 17
Strip tests of cross-linked B-staged A, B & C + TB films prepared
from fresh and aged formulafion

| | | | | | | | |
|---|---|---|---|---|---|---|---|
| | TB | | | | | | |
| | level, | | | −Strip | | −PSB | −Total |
| Cross-linking | wt % | Initial (nm) | Strip (nm) | (nm) | Final (nm) | (nm) | (nm) |

105C 5 hr B-staged A, B & C + TB Day 0

| | | | | | | | |
|---|---|---|---|---|---|---|---|
| 205C/10 min | 10 | 28.28 ± 0.04 | 27.88 ± 0.11 | −0.40 | 27.57 ± 0.08 | −0.31 | [symbol] |

105C 5 hr B-staged A & B + TB Day 31

| | | | | | | | |
|---|---|---|---|---|---|---|---|
| 205C/10 min | 10 | 24.92 ± 0.26 | 0.71 ± 0.61 | −24.21 | 0.47 ± 0.27 | −0.24 | [symbol] |

105C 5 hr B-staged A, B & C + TB Day 0

| | | | | | | | |
|---|---|---|---|---|---|---|---|
| 205C/10 min | 10 | 28.19 ± 0.09 | 27.73 ± 0.07 | −0.46 | 27.41 ± 0.08 | −0.32 | [symbol] |

105C 5 hr B-staged A, B & C + TB Day 31

| | | | | | | | |
|---|---|---|---|---|---|---|---|
| 205C/10 min | 10 | 27.10 ± 0.16 | 3.16 ± 1.37 | −23.94 | 3.05 ± 1.21 | −0.11 | [symbol] |

### General Experimental Procedures for OLED Device Manufacturing and Testing

To evaluate electroluminescent (EL) performances of the HTL layer in presence of acid p-dopant, the following types of OLED devices were fabricated for exploring the acid p-doping effect:
Type A ITO/AQ1200/HTL molecule (evaporative, 400 Å)/EML/ETL/Al
Type B: ITO/AQ1200/HTL polymer (soluble, 400 Å)/EML/ETL/Al
Type C: ITO/AQ1200/HTL polymer+acid p-dopant (soluble 400 Å)/EML/ETL/Al
   The thicknesses of Hole Injection Layer (HTL), Emission Material Layer (EML), Electron Transporting Layer (ETL) and cathode Al are 470, 400, 350 and 800 Å, respectively. Type A device was fabricated with evaporated HTL (same HTL core as HTL polymer) as evaporative control; Type B device was fabricated with solution processed HTL polymer as soluble control; Type C device was fabricated with solution processed HTL polymer plus 2 to 10 wt % acid p-dopant. Current density-voltage (J-V) characteristics, luminescence efficiency versus luminance curves, and luminescence decay curves of Type A-C devices were measured to evaluate the key device performance, specifically the driving voltage (at 1000 nit), current efficiency (at 1000 nit) and lifetime (15000 nit, after 10 hr). Type A to C Hole-Only Device (HOD) without EML and ETL layers were also prepared and tested for evaluating the hole mobility of the acid p-doped HTL.

### Example 18 Formulation of B-staged A,B&C and TB as HTL in OLED, HOD Device

Cross-linked B-staged A,B&C (Device 5, 6) gives reduced hole mobility than non cross-linked B-staged A,B&C (Device 4) in term of higher driving voltage.
TB doped cross-linked B-staged A,B&C (Device 7) gives higher hole mobility than cross-linked B-staged A,B&C (Device 5, 6) in term of lower driving voltage. As a result, TB doped cross-linked B-staged Monomers A,B&C (Device 7) gives longer lifetime than cross-linked B-staged A,B&C (Device 5, 6), which almost matches the evaporative control (Device 2).

TABLE 18-1
Summary table on B-staged A, B & C + TB as HTL in OLED device

| | | | | Voltage | | | lifetime | |
|---|---|---|---|---|---|---|---|---|
| | | | | [V, | | | [%, | |
| | | | | 1000 nit/ | | | 10 hr] | |
| | | | | 50 mA/c | Efficiency | | 15000 | EL |
| No. | OLED Device Structure | | | m²] | [Cd/A] | CIE | nits | [nm] |
| 1 | Evap. Ref T068(80 nm)/L101(3 nm)/ | | | 3.0/6.0 | 60.3 | 284 | 97.2% | 518 |
| | HTL-70(40 nm) | | | | | 670 | | |
| 2 | Plexcore | Evap. HTL-70(40 nm) | | 3.0/5.0 | 46.9 | 293 | 97.2% | 516 |
| | AQ1200 | | | | | 657 | | |
| | (47 nm) | | | | | | | |
| 4 | | B-staged A, B & C (40 nm) | 150C/ | 3.6, 6.4 | 50.8 | 292 | 60.2% | 516 |
| | | | 10 min | | | 656 | | |
| 5 | | B-staged A, B & C (39 nm) | 205C/ | 3.8/6.6 | 50.6 | 292 | 79.2% | 516 |
| | | | 5 min | | | 656 | | |
| 6 | | B-staged A, B & C (30 nm) | 205C/ | 4.2/7.3 | 49.1 | 293 | 72.0% | 516 |
| | | | 10 min | | | 655 | | |
| 7 | | B-staged A, B & C + TB (29 nm) | 205C/ | 3.6/6.4 | 49.5 | 295 | 95.8% | 516 |
| | | B-staged A, B & C: TB = 10:1 wt:wt | 5 min | | | 653 | | |

TB doped cross-linked B-staged A,B&C (Device 5) gives higher hole mobility than cross-linked B-staged A,B&C itself (Device 2) in term of lower driving voltage.
The hole mobility of TB doped cross-linked B-staged A,B&C (Device 5) gives higher hole mobility than the evaporative control (Device 1) in term of low driving voltage.

TABLE 18-2
Summary table on B-staged A, B&C + TB as HTL in HOD device

| | | | Voltage [10/100 |
|---|---|---|---|
| No. | HOD Device Structure | | mA/cm²] |
| 1 | Plexcore | Evap HTL-70 (40 nm) | 1.4/2.1 |
| 2 | AQ1200 | Cross-inked B-staged A, B&C | 1.9/3.0 |
| 5 | | Cross-linked B-staged | 1.1/2.1 |
| | | A, B&C + TB B-staged | |
| | | A, B&C:TB = 10:1 wt:wt | |

### Example 19 Formulation of High MW B6 Copolymer and TB as HTL in OLED, HOD Device

TB doped cross-linked high MW B6 copolymer (Device 8) gives higher hole mobility than cross-linked high MW B6 copolymer itself (Device 5) in term of lower driving voltage. As a result, TB doped cross-linked high MW B6 copolymer (Device 8) gives longer lifetime than cross-linked high MW B6 copolymer (Device 5), which almost matches the evaporative control (Device 2).
TB doped cross-linked high MW B6 copolymer (Device 8) gives similar performance to evaporative control (Device 1,2) in term of turn-on voltage, efficiency and lifetime.

TABLE 19-1
Summary table on High MW B6 + TB as HTL in OLED device

| | | | | | | | lifetime | |
|---|---|---|---|---|---|---|---|---|
| | | | | | | | [%, | |
| | | | | Voltage | | | 10 hr] | |
| | | | | [V, | Efficiency | | 15000 | EL |
| No. | OLED Device Structure | | | 1000 nit/ | [Cd/A] | CIE | nits | [nm] |
| 1 | Evap. Ref T068(80 nm)/L101(5 nm)/ | | | 3.0 | 65.5 | 312 | — | 520 |
| | HTL-70(40 nm) | | | | | 637 | | |
| 2 | Plexcore | Evap. HTL-70(40 nm) | | 2.9 | 53.8 | 319 | 98.4% | 516 |
| | AQ1200 | | | | | 628 | | |
| 5 | | High MW B6 | 205C/ | 4.2 | 62.1 | 315 | 71.1% | 516 |
| | | | 10 min | | | 659 | | |
| 8 | | High MW + TB | 205C/ | 2.9 | 62.8 | 316 | 95.8% | 516 |
| | | High MW B6: TB = 10:1 | | | | | | |
| | | wt:wt | 10 min | | | 628 | | |

TB doped cross-linked high MW B6 (Device 7) gives higher hole mobility than cross-linked high MW B6 itself (Device 4) in turn of lower driving voltage.
The hole mobility of TB doped cross-linked high MW B6 (Device 7) gives higher hole mobility than the evaporative control (Device 1) in term of lower driving voltage.

TABLE 19-2
Summary table on High MW B6 + TB as HTL in HOD device

| | | | Voltage [10/100 |
|---|---|---|---|
| No. | HOD Device Structure | | mA/cm²] |
| 1 | Plexcore | Evap HTL-70 (40 nm) | 1.4/2.1 |
| 4 | AQ1200 | Cross-linked High MW B6 | 2.4/3.5 |
| 7 | | Cross-linked High MW | 0.6/1.3 |
| | | B6 + TB | |
| | | Cross-linked High MW | |
| | | B6:TB = 10:1 wt:wt | |

### Example 20 Formulation of Low MW B2, Medium MW B4, B7 and TB as HTL in OLED, HOD Device

TB doped cross-linked low MW B2 homopolymer (Device 9) and medium MW B4, B7 copolymer (Device 10, 11) gives higher hole mobility than cross-linked low MW B2 (Device 6) and medium MW B4, B7 (Device 7,8) in term of lower driving voltage. As a result, TB doped cross-linked low MW B2 (Table 5-2 Device 9) and medium MW B4, B7 (Device 10, 11) gives longer lifetime than cross-linked low MW B2 (Device 6) and medium MW B4,B7 (Device 7, 8), which almost matches the evaporative control (Device 2).
TB doped cross-linked low MW B2, medium MW B4, B7 gives similar performance to evaporative control (Device 1,2) in term of turn-on voltage, efficiency and lifetime.

TABLE 20-1
Summary table on Low MW B2, Medium MW B4, B7 + TB as HTL in OLED device

| | | | | | | | lifetime | |
|---|---|---|---|---|---|---|---|---|
| | | | | | | | [%, | |
| | | | | Voltage | | | 10 hr] | |
| | | | | [V, | Efficiency | | 15000 | EL |
| No. | OLED Device Structure | | | 1000 nit] | [Cd/A] | CIE | nits | [nm] |
| 1 | Evap. Ref T068(80 nm)/L101(5 nm)/ | | | 2.9 | 75.6 | 305 | 98.1% | 520 |
| | HTL-70(40 nm) | | | | | 641 | | |
| 2 | Plexcore | Evap. HTL-70(40 nm) | | 3.0 | 65.0 | 316 | 97.9% | 516 |
| | AQ1200 | | | | | 629 | | |
| 3 | | Low MW B2 | 150C/ | 4.3 | 64.6 | 309 | 44.1% | 516 |
| | | | 10 min | | | 635 | | |
| 4 | | Medium MW B4 | 150C/ | 4.5 | 63.8 | 310 | 40.9% | 516 |
| | | | 10 min | | | 634 | | |
| 5 | | Medium MW B7 | 150C/ | 4.9 | 63.8 | 311 | 35.2% | 517 |
| | | | 10 min | | | 634 | | |
| 6 | | Low MW B2 | 205C/ | — | — | — | — | — |
| | | | 10 min | | | | | |
| 7 | | Medium MW B4 | 205C/ | 4.4 | 59.4 | 315 | 50.5% | 516 |
| | | | 10 min | | | 629 | | |
| 8 | | Medium MW B7 | 205C/ | 4.7 | 59.3 | 308 | 43.3% | 516 |
| | | | 10 min | | | 634 | | |
| 9 | | Low MW B2 + TB | 205C/ | 3.0 | 56.2 | 314 | 97.1% | 516 |
| | | Low MW B2: TB = | 10 min | | | 629 | | |
| | | 10:1 wt:wt | | | | | | |
| 10 | | Medium MW B4 | 205C/ | 3.1 | 62.9 | 311 | 95.5% | 516 |
| | | Medium MW B4: TB = | 10 min | | | 632 | | |
| | | 10:1 wt:wt | | | | | | |
| 11 | | Medium MW B4 | 205C/ | 3.2 | 65.7 | 308 | 94.5% | 516 |
| | | Medium MW B4: TB = | 10 min | | | 634 | | |
| | | 10:1 wt:wt | | | | | | |

TB doped cross-linked low MW B2 homopolymer (Device 8) and medium MW B4, B7 copolymer (Device 9, 10) gives higher hole mobility than cross-linked low MW B2 (Device 5) and medium MW B4, B7 (Device 6, 7), as well as non-cross-linked low MW B2 (Device 2) and medium MW B4, B7 (Device 3, 4) in tam of lower driving voltage.
TB doped cross-linked low MW B, medium MW B4, B7 (Device 8, 9, 10) gives similar or higher hole mobility than evaporative control (Device 1).

TABLE 20-2
Summary table on Low MW B2, Medium
MW B4, B7 + TB as HTL in HOD device

| | | | | Voltage |
|---|---|---|---|---|
| | | | | [10/100 |
| No. | HOD Device Structure | | | mA/cm²] |
| 1 | Plexcore | Evap HTL-70 (40 nm) | 150 C./10 min | 1.8/4.8 |
| 2 | AQ1200 | Low MW B2 | 150 C./10 min | 3.2/5.9 |
| 3 | | Medium MW B4 | 150 C./10 min | 3.3/7.1 |
| 4 | | Medium MW B7 | 205 C./10 min | 3.6/7.2 |
| 5 | | Low MW B2 | 205 C./10 min | 2.8/5.8 |
| 6 | | Medium MW B4 | 205 C./10 min | 3.3/6.9 |
| 7 | | Medium MW B7 | 205 C./10 min | 3.6/7.1 |
| 8 | | Low MW B2 + TB | 205 C./10 min | 1.2/3.8 |
| | | Low MW | | |
| | | B2:TB = 10:1 wt:wt | | |
| 9 | | Medium MW B4 | 205 C./10 min | — |
| | | Medium MW | | |
| | | B4:TB = 10:1 wt:wt | | |
| 10 | | Medium MW B4 | 150 C./10 min | 1.8/4.8 |
| | | Medium MW | | |
| | | B4:TB = 10:1 wt:wt | | |

### Example 21 Formulation of High MW B1 and TB/HB as HTL in OLED Device

TB/HB doped cross-linked high MW B1 homopolymer (Device 5, 6) gives higher hole mobility than cross-linked high MW B1 itself (Device 4) in item of lower driving voltage.
TB/HB doped cross-linked high MW B1 (Device 5, 6) gives similar performance to evaporative control (Device 2) in teams of driving voltage and lifetime. The efficiency is higher for 113/HB doped cross-linked high MW B1 (Device 5, 6 vs. 2).

TABLE 21-1
Summary table on High MW B1 + TB/HB as HTL in OLED device

| | | | | | | | lifetime | |
|---|---|---|---|---|---|---|---|---|
| | | | | | | | [%, | |
| | | | | Voltage | | | 10 hr] | |
| | | | | [V, | Efficiency | | 15000 | EL |
| No. | OLED Device Structure | | | 1000 nit] | [Cd/A] | CIE | nits | [nm] |
| 1 | Evap. Ref T068(80 nm)/L101(5 nm)/ | | | 3.0 | 58.8 | 307 | 98.2% | 516 |
| | HTL-70(40 nm) | | | | | 637 | | |
| 2 | Plexcore | Evap. HTL-70(40 nm) | | 3.0 | 54.2 | 318 | 97.5% | 516 |
| | AQ1200 | | | | | 629 | | |
| 4 | | High MW B1 | 205C/ | 3.2 | 67.2 | 314 | 94.3% | 516 |
| | | | 10 min | | | 630 | | |
| 5 | | High MW B1 + TB | 205C/ | 3.0 | 64.4 | 311 | 95.3% | 516 |
| | | High MW B1: TB = | 10 min | | | 631 | | |
| | | 100:2 wt:wt | | | | | | |
| 6 | | High MW B1 + HB | 205C/ | 3.0 | 63.3 | 315 | 94.8% | 516 |
| | | High MW B1: TB = | 10 min | | | 628 | | |
| | | 100:2 wt:wt | | | | | | |

1. A single liquid phase formulation useful for producing an organic charge transporting film; said formulation comprising: (a) a polymer resin having M_{w} at least 3,000 and comprising arylmethoxy linkages; (b) an acid catalyst which is an organic Bronsted acid with pKa≤4; a Lewis acid comprising a positive aromatic ion and an anion which is (i) a tetraaryl borate having the formula 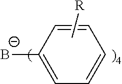
wherein R represents zero to five non-hydrogen substituents selected from D, F and CF₃, (ii) BF₄⁻, (iii) PF₆⁻, (iv) SbF₆⁻, (v) AsF₆⁻ or (vi) ClO₄⁻; or a thermal acid generator which is an ammonium or pyridinium salt of an organic Bronsted acid with pKa≤4 or an ester of an organic sulfonic acid; and (c) a solvent.

2. The formulation of claim 1 in which the polymer resin has M_{w} from 5,000 to 100,000.

3. The formulation of claim 2 comprising from 0.5 to 10 wt % polymer resin, from 0.01 to 1 wt % acid catalyst and from 90 to 99.5 wt % solvent.

4. The formulation of claim 3 in which the solvent has a Hansen RED value relative to the polymer resin less than 1.

5. A method of making an organic charge transporting film; said method comprising steps of: (a) coating on a surface a formulation comprising: (i) a polymer resin having M_{w} at least 5,000 and comprising arylmethoxy linkages; (ii) an acid catalyst which is an organic Bronsted acid with pKa≤4; a Lewis acid comprising a positive aromatic ion and an anion which is (i) a tetraaryl borate having the formula 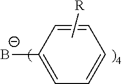
wherein R represents zero to five non-hydrogen substituents selected from D, F and CF₃, (ii) BF₄⁻, (iii) PF₆⁻, (iv) SbF₆⁻, (v) AsF₆⁻ or (vi) ClO₄⁻; or a thermal acid generator which is an ammonium or pyridinium salt of an organic Bronsted acid with pKa≤2 or an ester of an organic sulfonic acid; and (iii) a solvent; and (b) heating the coated surface to a temperature from 120 to 280° C.

6. The method of claim 5 in which the polymer resin has M_{w} from 5,000 to 100,000.

7. The method of claim 6 in which the formulation comprises from 0.5 to 10 wt % polymer resin, from 0.01 to 1 wt % acid catalyst and from 90 to 99.5 wt % solvent.

8. The method of claim 7 in which the solvent has a Hansen RED value relative to the polymer resin less than 1.

9. The method of claim 8 in which the coated surface is heated to a temperature from 140 to 230° C.

10. An electronic device comprising one or more organic charge transporting films made by the method of claim 5.

11. A light emitting device comprising one or more organic charge transporting films made by the method of claim 5.
